(19) United States
(12) Patent Application Publication
(10) Pub. No.: US 2021/0050517 A1
(43) Pub. Date: Feb. 18, 2021

(54) SEMICONDUCTOR DEVICE

(71) Applicant: NEC Corporation, Minato-ku, Tokyo (JP)

(72) Inventors: Naoki BANNO, Tokyo (JP); Munehiro TADA, Tokyo (JP)

(73) Assignee: NEC Corporation, Minato-ku, Tokyo (JP)

(21) Appl. No.: 17/041,772

(22) PCT Filed: Apr. 15, 2019
(86) PCT No.: PCT/JP2019/016072

§ 371 Date: Sep. 25, 2020

(30) Foreign Application Priority Data
Apr. 17, 2018 (JP) 2018-079029

(51) Int. Cl. H01L 45/00; H01L 27/24

(52) U.S. Cl. CPC H01L 45/1266; H01L 27/2463; H01L 45/085; H01L 45/1683; H01L 45/1675

(57) ABSTRACT

A semiconductor device includes a first insulation layer, a second insulation layer disposed on the first insulation layer and having an opening on an upper surface of the second insulation layer, a first electrode embedded in the second insulation layer and having an end exposed at the opening, a variable-resistance layer disposed on the first electrode and the second insulation layer in at least one region inside and around the opening, and a second electrode disposed on the variable-resistance layer. The opening and the second electrode are formed in a shape stretched in at least one axial direction.

### TECHNICAL FIELD

The present invention relates to a semiconductor device having a switching element including a variable-resistance element.

### BACKGROUND ART

In order to diversify the functions of programmable logic and promote its implementation in electronic equipment or the like, it is required to reduce the size of a switching element that interconnects logic cells and to reduce the on-resistance of the switching element. A switching element that utilizes precipitation of a metal in an ion conductive layer has a smaller size and a smaller on-resistance than those of a general semiconductor switch, and thus the element size can be reduced.

PTL 1 discloses a two-terminal type switching element (hereinafter referred to as two-terminal switch) including an ion conductive layer. The two-terminal switch of PTL 1 has a structure in which an ion conductive layer is sandwiched between a first electrode that supplies a metal ion and a second electrode that does not supply a metal ion. The two-terminal switch of PTL 1 can be switched by controlling a voltage applied between the two electrodes to form and extinguish a metal bridge in the ion conductive layer. Since the two-terminal switch has an uncomplicated structure, the fabrication process is simple and the two-terminal switch can be worked to a small element size of the nanometer order.

PTL 2 discloses a three-terminal type switching element (hereinafter referred to as three-terminal switch). The three-terminal switch of PTL 2 has a structure in which second electrodes of two two-terminal switches are integrated. According to the three-terminal switch of PTL 2, high reliability can be ensured.

In order to implement the switching elements disclosed in PTLs 1 and 2 as wiring changeover switches for programmable logic, it is required, for example, to downsize and densify the switching elements and to simplify the manufacturing step. The wiring of the most progressive semiconductor device is copper wiring mainly composed of copper. Therefore, a technique of efficiently forming a variable-resistance element by actively utilizing the copper wiring is desired.

PTLs 3 and 4 disclose a technology of integrating a switching element by using a copper wiring on a semiconductor substrate also as a first electrode of the switching element. The use of the structure of the first electrode disclosed in PTLs 3 and 4 can exclude the step for newly forming the first electrode. Therefore, a mask for forming the first electrode is no longer necessary, and the number of photomasks to be added when manufacturing the variable-resistance element is only two, such that the manufacturing cost can be lessened.

PTL 5 discloses a variable-resistance element including: a variable-resistance film; a first electrode disposed as a wiring on one surface of the variable-resistance film and having a curved end; and a second electrode disposed as an inert electrode on another surface of the variable-resistance film. A corner of the first electrode of the variable-resistance element of PTL 5 is located at the curved end and makes contact with the variable-resistance film inserted in an opening formed in an insulating barrier film. In the variable-resistance element of PTL 5, the electric field is concentrated at the corner of the first electrode located at an end of a copper wiring. When the exposure amount of the corner of the copper wiring is made larger at the opening of the insulating barrier film, the electric field concentration region is increased, such that switching is performed in a region where electric field concentration is likely to occur, and variation in switching voltage can be lessened.

PTL 6 discloses a semiconductor device incorporating a nonvolatile element. The nonvolatile element of the semiconductor device of PTL 6 includes a resistance-changing film, an upper electrode disposed on the top of the resistance-changing film, and a lower electrode disposed below the resistance-changing film. The resistance-changing film is electrically connected to each of a lower layer wiring disposed on a lower layer side of the resistance-changing film and an upper layer wiring disposed on an upper layer side of the resistance-changing film. A lower electrode is also used as the lower layer wiring or is electrically connected to the lower layer wiring directly or via a conducting film. An upper electrode has an upper surface in which a step is formed between a central portion and an outer peripheral portion, and at least the outer peripheral portion on the upper surface is directly connected to the upper layer wiring or electrically connected via a conducting film.

### CITATION LIST

### Patent Literature

[PTL 1] JP 2002-536840 A

[PTL 2] WO 2012/043502 A

[PTL 3] WO 2011/158821 A

[PTL 4] JP 5382001 B2

[PTL 5] JP 6112106 B2

[PTL 6] WO 2011/142386 A

### SUMMARY OF INVENTION

### Technical Problem

When the miniaturization of the switching element is advanced as in PTLs 1 and 2, high-cost exposure apparatus and mask are required, which leads to an increase in manufacturing cost.

In the structure in which the corner of the copper wiring is exposed at the opening of the insulating barrier film as in PTL 5, if the miniaturization is excessively advanced, the exposure amount of the corner of the copper wiring at the opening is decreased, and thus the element characteristics are degraded. In the case of a two-terminal switch or a three-terminal switch structure, in order to expand the exposure amount of the corner of the copper wiring at the opening, it is necessary to expand the opening area of the insulating film on the copper wiring, which hinders scaling.

It is an object of the present invention to solve the above problems and to provide a switching element that has been miniaturized without an increase in manufacturing cost and for which a switching voltage variation increase accompanied by miniaturization has been suppressed.

### Solution to Problem

A semiconductor device according to one aspect of the present invention includes: a first insulation layer; a second insulation layer disposed on the first insulation layer and having an opening on an upper surface of the second insulation layer; a first electrode embedded in the second insulation layer and having an end that is exposed at the opening; a variable-resistance layer disposed on the first electrode and the second insulation layer in at least one region inside and around the opening; and a second electrode that is disposed on the variable-resistance layer. The opening and the second electrode are formed in a shape stretched in at least one axial direction.

A semiconductor device according to one aspect of the present invention includes: a first insulation layer; a second insulation layer disposed on the first insulation layer and has an opening on an upper surface of the second insulation layer; at least one first wiring embedded in the second insulation layer and extended in a first direction, and at least one end of the at least one first wiring constitutes a first electrode exposed at the opening; a variable-resistance layer disposed on the first wiring and the second insulation layer in at least one region inside and around the opening; a second electrode disposed on the variable-resistance layer; a third insulation layer disposed above the first electrode, the variable-resistance layer, and the second electrode; at least one second wiring embedded in the third insulation layer via a barrier metal and extended in a second direction intersecting the first direction; and a via embedded in the third insulation layer integrally with the second wiring via the barrier metal and electrically connected to the second electrode via the barrier metal. The opening and the second electrode are formed in a shape stretched in at least one axial direction.

### Advantageous Effects of Invention

According to the present invention, it is possible to provide a switching element that has been miniaturized without an increase in manufacturing cost and for which a switching voltage variation increase accompanied by miniaturization has been suppressed.

### BRIEF DESCRIPTION OF DRAWINGS

FIG. 1 is a schematic cross-sectional view illustrating an example of the configuration of a semiconductor device according to a first example embodiment of the present invention.

FIG. 2 is a conceptual diagram for explaining an example of the shape of an opening made in a second insulation layer and the exposed state of a first electrode at the opening in the semiconductor device according to the first example embodiment of the present invention.

FIG. 3 is a conceptual diagram for explaining another example of the shape of the opening made in the second insulation layer and the exposed state of the first electrode at the opening in the semiconductor device according to the first example embodiment of the present invention.

FIG. 4 is a conceptual diagram for explaining an example of the shape of an opening made in a second insulation layer and the exposed state of a first electrode at the opening in a first modification of the semiconductor device according to the first example embodiment of the present invention.

FIG. 5 is a schematic cross-sectional view illustrating an example of the configuration of the first modification of the semiconductor device according to the first example embodiment of the present invention.

FIG. 6 is a conceptual diagram for explaining an example of the shape of an opening made in a second insulation layer and the exposed state of a first electrode at the opening in a second modification of the semiconductor device according to the first example embodiment of the present invention.

FIG. 7 is a conceptual diagram for explaining an example of the shape of an opening made in a second insulation layer and the exposed state of a first electrode at the opening in a third modification of the semiconductor device according to the first example embodiment of the present invention.

FIG. 8 is a conceptual diagram for explaining an example of the shape of an opening made in a second insulation layer and the exposed state of first electrodes at the opening in a semiconductor device according to related art.

FIG. 9 is a conceptual diagram for explaining an example of disposing a semiconductor device according to the related art.

FIG. 10 is a conceptual diagram for explaining an example of disposing the semiconductor device according to the first example embodiment of the present invention.

FIG. 11 is a conceptual diagram for explaining an example of raising the density to dispose the semiconductor devices according to the related art.

FIG. 12 is a conceptual diagram for explaining an example of raising the density to dispose the semiconductor devices according to the first example embodiment of the present invention.

FIG. 13 is a schematic cross-sectional view illustrating an example of the configuration of a semiconductor device according to a second example embodiment of the present invention.

FIG. 14 is a schematic cross-sectional view for explaining step 1 of a method of manufacturing the semiconductor device according to the second example embodiment of the present invention.

FIG. 15 is a schematic cross-sectional view for explaining step 2 of the method of manufacturing the semiconductor device according to the second example embodiment of the present invention.

FIG. 16 is a schematic cross-sectional view for explaining step 3 of the method of manufacturing the semiconductor device according to the second example embodiment of the present invention.

FIG. 17 is a schematic cross-sectional view for explaining step 4 of the method of manufacturing the semiconductor device according to the second example embodiment of the present invention.

FIG. 18 is a schematic cross-sectional view for explaining step 5 of the method of manufacturing the semiconductor device according to the second example embodiment of the present invention.

FIG. 19 is a schematic cross-sectional view for explaining step 6 of the method of manufacturing the semiconductor device according to the second example embodiment of the present invention.

FIG. 20 is a schematic cross-sectional view for explaining step 7 of the method of manufacturing the semiconductor device according to the second example embodiment of the present invention.

FIG. 21 is a schematic cross-sectional view for explaining step 8 of the method of manufacturing the semiconductor device according to the second example embodiment of the present invention.

FIG. 22 is a schematic cross-sectional view for explaining step 9 of the method of manufacturing the semiconductor device according to the second example embodiment of the present invention.

FIG. 23 is a schematic cross-sectional view for explaining step 10 of the method of manufacturing the semiconductor device according to the second example embodiment of the present invention.

FIG. 24 is a schematic cross-sectional view for explaining step 11 of the method of manufacturing the semiconductor device according to the second example embodiment of the present invention.

FIG. 25 is a schematic cross-sectional view for explaining step 12 of the method of manufacturing the semiconductor device according to the second example embodiment of the present invention.

FIG. 26 is a schematic cross-sectional view illustrating an example of the configuration of a semiconductor device according to a third example embodiment of the present invention.

### EXAMPLE EMBODIMENT

Modes for carrying out the present invention will be described below with reference to the accompanying drawings. However, while the example embodiments described below are limited to technologically preferred ones for carrying out the present invention, the scope of the invention is not limited to the following. In all the figures used in the following explanation of the example embodiments, the same reference signs are given to similar portions unless there is a particular reason. In the following example embodiments, a repetitive description of similar configuration and operation is omitted in some cases.

### First Example Embodiment

First, a semiconductor device according to a first example embodiment of the present invention will be described with reference to the drawings. The semiconductor device of the present example embodiment has a configuration including a switching element inside a multilayer wiring layer formed on a substrate (not illustrated). The semiconductor device of the present example embodiment has a conceptual configuration for explaining characteristic portions of the present example embodiment, and does not accurately represent the scale, shape, and the like.

[Configuration]

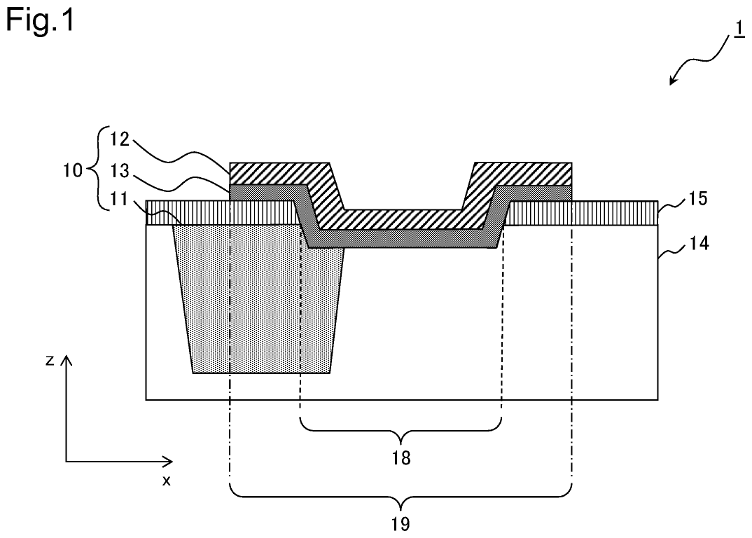

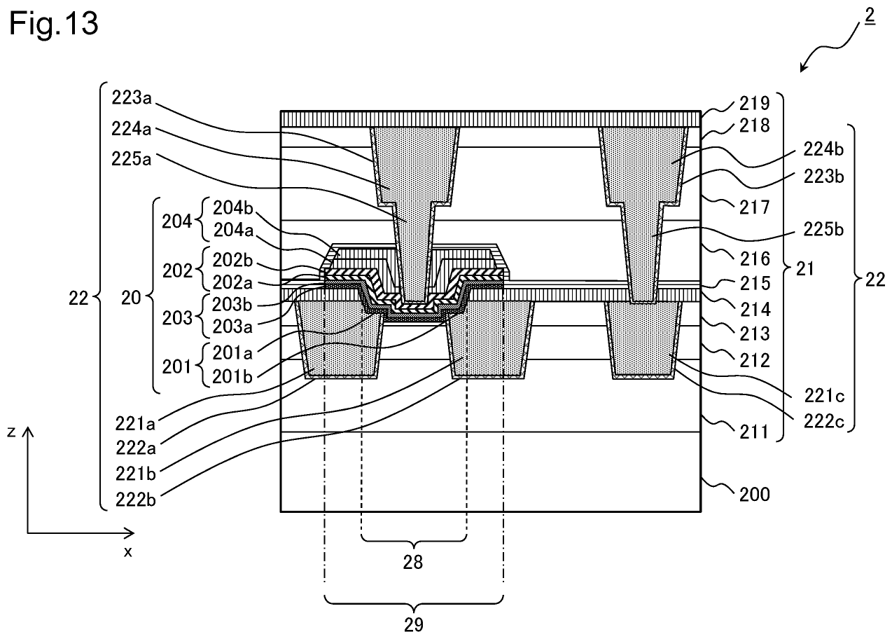

FIG. 1 is a cross-sectional view for explaining an example of the configuration of the semiconductor device 1 of the present example embodiment. As illustrated in FIG. 1, the semiconductor device 1 includes a first electrode 11, a second electrode 12, a variable-resistance layer 13, a first insulation layer 14, and a second insulation layer 15. The first electrode 11, the second electrode 12, and the variable-resistance layer 13 constitute a switching element 10. The switching element 10 illustrated in FIG. 13 is a two-terminal type switching element (also called a two-terminal switch). When a three-terminal type switching element (also called a three-terminal switch) is configured, it suffices that two first electrodes 11 are formed to face each other in such a way that two switching elements 10 are configured.

The second insulation layer 15 has an opening 18. The opening 18 is made in such a way as to taper toward a depth direction (−Z direction). That is, an inner surface of the opening 18 made in the second insulation layer 15 forms a tapered surface that tapers toward the depth direction. FIG. 1 illustrates an example in which the opening 18 made in the second insulation layer 15 is dug down to an upper part of the first insulation layer 14 and the first electrode 11. The first electrode 11 may not be dug down in the depth direction in the opening region of the opening 18.

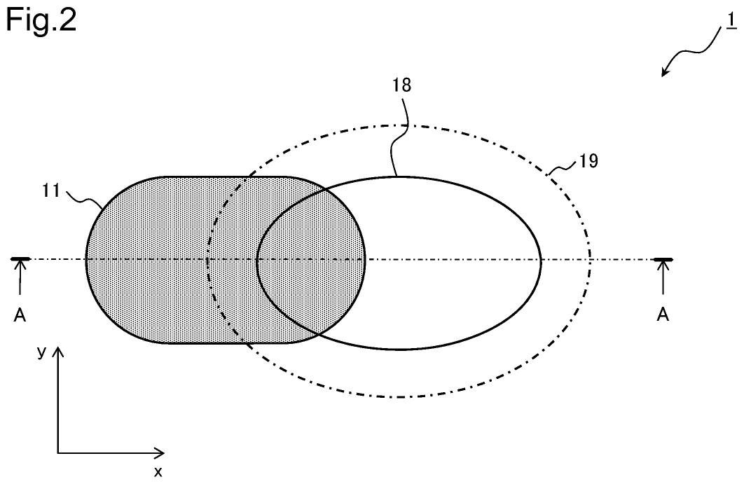

FIG. 2 is a schematic top view of the semiconductor device 1 as viewed from a viewpoint on an upper surface side. FIG. 1 corresponds to a cross-sectional view taken along an A-A section line in FIG. 2. When the semiconductor device 1 is viewed from the viewpoint on the upper surface side, a region where the second electrode 12 is formed (also referred to as a second electrode formation region) is called a second electrode region 19.

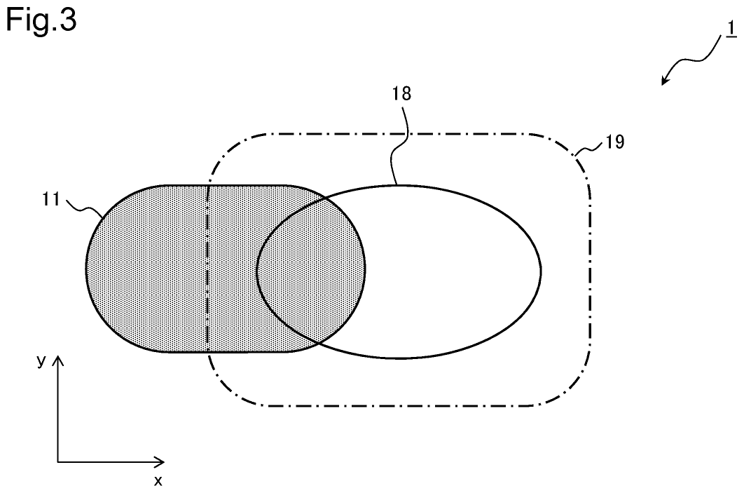

FIG. 2 illustrates the shape of the opening 18 made in the first insulation layer 14 and the second insulation layer 15, and the exposed state of the first electrode 11 at the opening 18. FIG. 2 exemplifies the second electrode region 19 having an elliptical shape. The second electrode region 19 may be configured into a rounded rectangular shape as illustrated in FIG. 3.

The shape of the second electrode region 19 may be a lengthened shape along an x-axis direction, and is not limited to the shapes illustrated in FIGS. 2 and 3. The opening 18 and the second electrode region 19 are each a region with an elongated shape having a major axis (also called a long side) along the x-axis and a minor axis (also called a short side) along a y-axis direction. In other words, the shapes of the opening 18 and the second electrode region 19 are axially symmetrical about the x-axis and the y-axis, and have a two-fold symmetric property in a xy-plane. For example, the second electrode region 19 has a shape inscribed in a rectangle.

As illustrated in FIG. 2, the opening 18 has a major axis in the same direction as a major axis direction (x-axis direction) of the first electrode 11. For example, the opening region of the opening 18 has a shape inscribed in a rectangle. For example, the shape of the opening 18 is configured in such a way that the ratio of the length of the long side to the short side is equal to or more than 1.4 but equal to or less than 1.8.

The first electrode 11 is an end of an active electrode embedded in a wiring groove formed in the first insulation layer 14 laminated on the substrate. As illustrated in FIG. 2, the first electrode 11 has an elongated shape having a major axis (also called a long side) along the x-axis and a minor axis (also called a short side) along the y-axis direction. The directions of the major axis and the minor axis of the first electrode 11 coincide with those of the opening 18 made in the second insulation layer 15. For example, the shape of the first electrode 11 is configured in such a way that the ratio of the length of the major axis to the minor axis is equal to or more than 1.4 but equal to or more than 1.8.

The first electrode 11 is a part of the first wiring, which is a member of the multilayer wiring layer formed on the substrate. The second insulation layer 15 is laminated on the top of the first electrode 11. The first electrode 11 is exposed at the opening 18 made in the second insulation layer 15 as viewed from the viewpoint on the upper surface side of the substrate. The exposed part of the first electrode 11 is covered with the variable-resistance layer 13 at the opening 18 made in the second insulation layer 15.

For the first electrode 11, a metal capable of diffusing or conducting ions in the variable-resistance layer 13 is used. For example, a metal mainly composed of copper is used for the first electrode 11. For example, the first electrode 11 may be constituted by copper or may be constituted by an alloy of aluminum and copper, or the like.

The second electrode 12 is an inert electrode laminated on the variable-resistance layer 13. An insulation layer (not illustrated) is formed above the second electrode 12, and a via (not illustrated) and a second wiring are embedded inside the insulation layer. The second electrode 12 is connected to the second wiring by the via (not illustrated).

The second electrode 12 is constituted by a material that is harder to ionize than a metal included in the first electrode 11. For the second electrode 12, it is preferable to use an alloy of a metal that is hard to diffuse or conduct ions in the variable-resistance layer 13, and a metal having good adhesion to a metal included in the first electrode 11. For example, a ruthenium alloy that is hard to diffuse or conduct ions in the variable-resistance layer 13 can be used for the second electrode 12. When the ruthenium alloy is used for the second electrode 12, it is preferable that titanium, tantalum, zirconium, hafnium, aluminum, or the like having good adhesion to a metal included in the first electrode 11 be contained as a first metal.

For example, when the ruthenium alloy is used for the second electrode 12, it is desirable to select, as the first metal, an additive metal having a larger standard Gibbs energy of formation in a negative direction than ruthenium in the course of generating metal ions from the metal (oxidation course). For example, since titanium, tantalum, zirconium, hafnium, and aluminum are more likely to undergo spontaneous chemical reactions than ruthenium, by alloying these metals with ruthenium, adhesion to a metal bridge formed by a metal included in the first electrode 11 is enhanced.

When copper, which is a component of the metal bridge, is mixed into the second electrode 12, the effect of adding a metal having a larger standard Gibbs energy of formation in the negative direction to the second electrode 12 is weakened. Therefore, the metal added to ruthenium is preferably a material having a barrier property against copper and copper ions, such as tantalum and titanium.

The larger the amount of the additive metal, the more stable the low-resistance state (on-state) of the switching element 10. The stability of the low-resistance state of the switching element 10 is enhanced even when an additive metal of about five atomic percent is added. In particular, when titanium is used as the additive metal, the transition to the high-resistance state (off-state) and the stability of the low-resistance state (on-state) are excellent. In particular, when an alloy of ruthenium and titanium is used for the second electrode 12 and the content ratio of titanium is set in the range of 20 to 30 atomic percent, the transition to the high-resistance state and the stability of the low-resistance state are made better. When the second electrode 12 is constituted by a ruthenium alloy, ruthenium is preferably set to a content ratio equal to or more than 60 atomic percent but equal to or less than 90 atomic percent.

The variable-resistance layer 13 is laminated on the second insulation layer 15, and covers the first electrode 11 inside the opening 18 made in the second insulation layer 15. A metal included in the first electrode 11 is ionized and diffused into the variable-resistance layer 13. In other words, the variable-resistance layer 13 is an ion conductive layer capable of conducting ions of a metal constituting the first electrode 11. By controlling the voltage or current applied between the first electrode 11 and the second electrode 12, metal ions diffused inside the variable-resistance layer 13 can be precipitated.

The variable-resistance layer 13 is a film whose electrical resistance changes. For the variable-resistance layer 13, it is possible to use a material whose electrical resistance changes depending on actions such as diffusion or ion conduction of metal ions generated from a metal included in the first electrode 11. In particular, when the resistance state of the switching element 10 is controlled by precipitation of metal caused by reduction of metal ions, a material capable of conducting ions is used for the variable-resistance layer 13.

The variable-resistance layer 13 makes contact with upper surfaces of the first electrode 11 and the first insulation layer 14 in an internal region of the opening 18, and also makes contact with the tapered surface formed in the first electrode 11, the first insulation layer 14, and the second insulation layer 15. The variable-resistance layer 13 makes contact with an upper surface of the second insulation layer 15 in a peripheral region of the opening 18.

Turning on and off the switching element 10 can be controlled by applying a voltage or passing a current. For example, turning on and off the switching element 10 can be controlled by utilizing a phenomenon in which metal ions supplied from a metal included in the first electrode 11 are subjected to electrolytic diffusion into the variable-resistance layer 13. When a metal bridge is produced between the first electrode 11 and the second electrode 12, the switching element 10 transits to a low-resistance state (also called an on-state). When the metal bridge between the first electrode 11 and the second electrode 12 is broken, the switching element 10 transits to a high-resistance state (also called an off-state).

The first insulation layer 14 is an insulating film formed on the substrate. A wiring groove for embedding the first wiring is formed in the first insulation layer 14. The first wiring is embedded in the wiring groove formed in the first insulation layer 14. The first insulation layer 14 may have a structure in which a plurality of insulation layers is laminated. For example, a silicon oxide film (SiO film), a carbon-added silicon oxide film (SiOC film), or the like can be used for the first insulation layer 14.

The second insulation layer 15 is formed on the first electrode 11 and the first insulation layer 14. The second insulation layer 15 prevents oxidation of a metal constituting the first electrode 11 and prevents diffusion of a metal constituting the first electrode 11 into the first insulation layer 14. The second insulation layer 15 functions as an etching stop layer when the second electrode 12 and the variable-resistance layer 13 are worked. For example, a silicon carbide film, a silicon carbonitride film, a silicon nitride film, and a laminated structure of these films can be used for the second insulation layer 15.

The above is the description of an example of the configuration of the semiconductor device 1 of the present example embodiment. The shape and configuration of the semiconductor device 1 illustrated in FIGS. 1 to 3 are merely examples, and diverse modifications and additions can be made.

[Modifications]

Here, modifications of the semiconductor device 1 of the present example embodiment will be described with reference to the drawings. The following modifications relate to variations in the exposed state of the first electrode 11 at the opening 18.

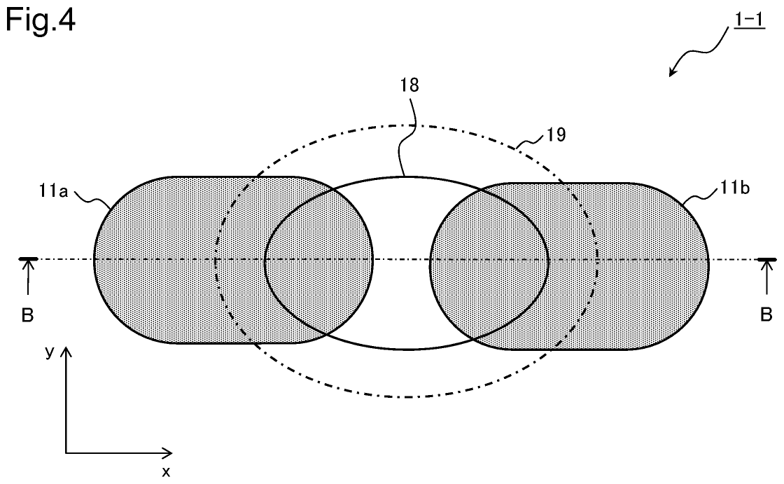

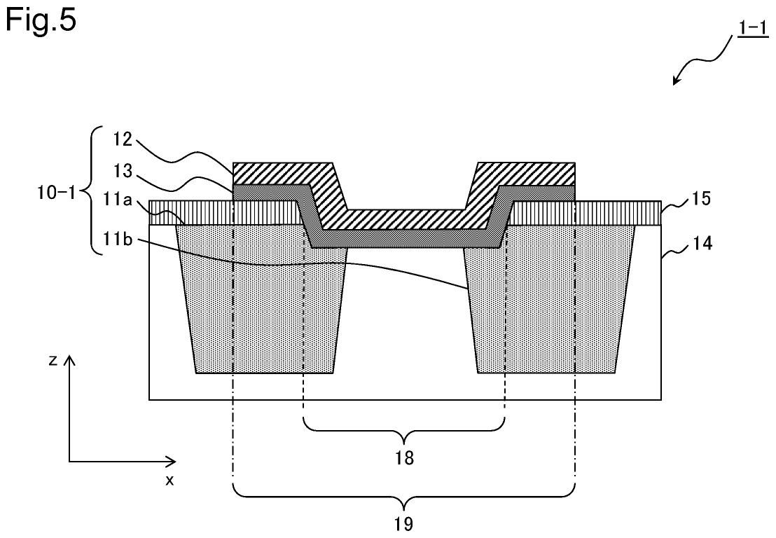

FIG. 4 is a top view for explaining the shape of an opening 18 made in a second insulation layer 15 and the exposed state of a first electrode 11 at the opening 18 in a semiconductor device 1-1 of a first modification. FIG. 5 is a schematic cross-sectional view illustrating an example of the configuration of the semiconductor device 1-1 of the first modification. FIG. 4 corresponds to a cross-sectional view taken along a B-B section line in FIG. 5.

As illustrated in FIG. 4, in the first modification, a first electrode 11a and a first electrode 11b are disposed to face each other with the minor axis sandwiched therebetween. The first electrode 11a is configured similarly to the first electrode 11 in FIG. 1. The first electrode 11b is configured similarly to the first electrode 11 in FIG. 1 in such a way as to face the first electrode 11a. The first electrode 11a, the first electrode 11b, a second electrode 12, and a variable-resistance layer 13 constitute a three-terminal type switching element 10-1 (also called a three-terminal switch).

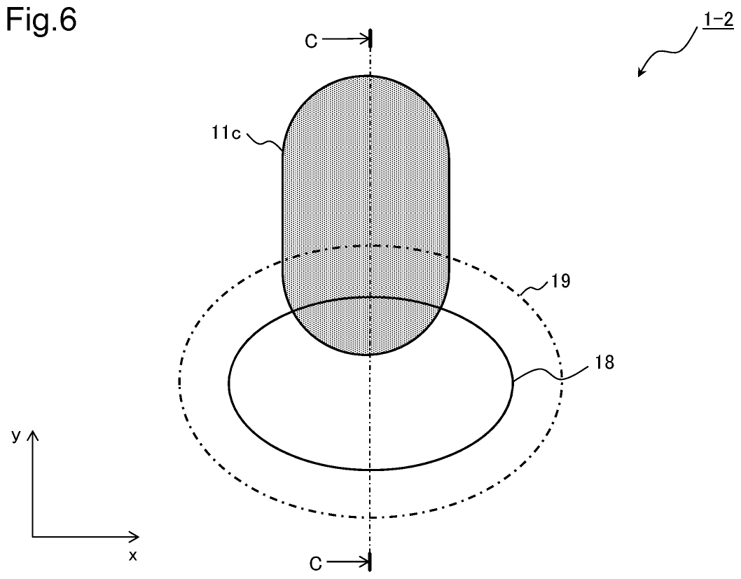

FIG. 6 is a top view for explaining the shape of an opening 18 made in a second insulation layer 15 and the exposed state of a first electrode 11 at the opening 18 in a semiconductor device 1-2 of a second modification. As illustrated in FIG. 6, in the second modification, the major axis (y-axis direction) of a first electrode 11c and the major axis (x-axis direction) of the opening 18 are made perpendicular to each other. The first electrode 11c is configured similarly to the first electrode 11 in FIG. 1. In the case of the configuration in FIG. 6, FIG. 1 corresponds to a cross-sectional view taken along a C-C section line in FIG. 6.

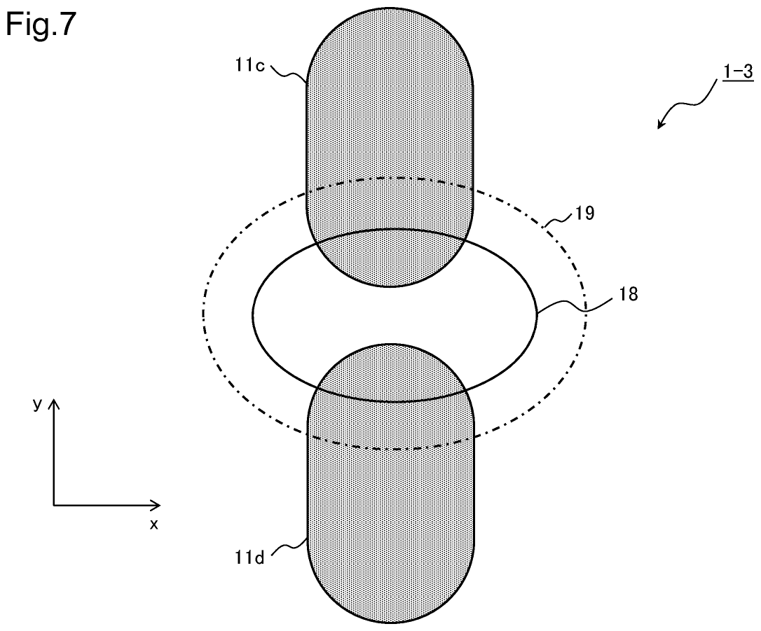

FIG. 7 is a top view for explaining the shape of an opening 18 made in a second insulation layer 15 and the exposed state of a first electrode 11 at the opening 18 in a semiconductor device 1-3 of a third modification. As illustrated in FIG. 6, in the third modification, a first electrode 11c and a first electrode 11d are disposed to face each other with the major axis sandwiched therebetween. The first electrodes 11c and 11d are configured similarly to the first electrodes 11a and 11b in FIG. 4. According to the third modification, a three-terminal switch can be achieved as in the first modification.

### RELATED ART

Here, in order to explain the effect of the semiconductor device 1 of the present example embodiment, a semiconductor device 100 according to related art will be described. The semiconductor device 100 of the related art is different from the semiconductor device 1 of the present example embodiment in the shape of the opening in the second insulation layer and the shape of the second electrode. In the following, the configuration of the semiconductor device 1-1 of the first modification as the semiconductor device 1 of the present example embodiment will be described as a comparative object.

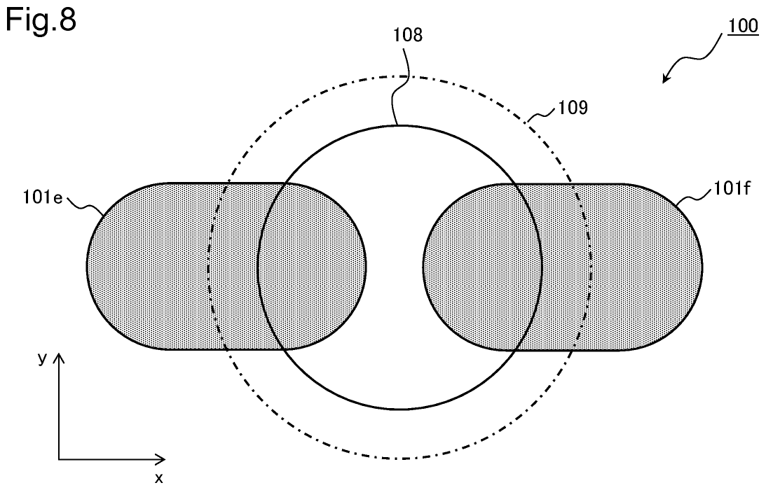

FIG. 8 is a conceptual diagram for explaining an example of the shape of an opening 108 made in a second insulation layer of the semiconductor device 100 of the related art and the exposed state of a first electrode 101e and a first electrode 101f at the opening 108. FIG. 8 also illustrates a region where a second electrode is formed (second electrode region 109) when the semiconductor device 100 is viewed from the viewpoint on the upper surface side. As illustrated in FIG. 8, an opening region of the opening 108 and the second electrode region 109 are circular as viewed from the viewpoint on the upper surface side of a substrate. The cross-sectional structure of the semiconductor device 100 of the related art is similar to the cross-sectional structure in FIG. 1. When the first electrode 101e is not distinguished from the first electrode 101f, the first electrodes 101e and 101f are referred to as first electrodes 101.

In the semiconductor device 100 of the related art in FIG. 8, as viewed from the viewpoint above the substrate, the shape of the opening region of the opening 108 is circular and the shape of the second electrode region 109 is also circular. The shape of the opening region of the opening 108 and the shape of the second electrode region 109 may be a square or a rounded square or the like. That is, in the semiconductor device 100 of the related art, the shapes of the opening region of the opening 108 and the second electrode region 109 are axially symmetrical about the x-axis and the y-axis, and have a four-fold symmetric property in the xy-plane.

On the other hand, in the semiconductor device 1-1 of the present example embodiment, the shapes of the opening 18 and the second electrode region 19 are axially symmetrical about the x-axis and the y-axis, and have a two-fold symmetric property in the xy-plane.

The first electrodes 101e and 101f are exposed in such a way as to face each other in the opening region of the opening 108. When a voltage is applied between the first electrode 101 and a second electrode (not illustrated), the electric field is concentrated on an edge portion where the surface morphology is larger. The longer the perimeter of an edge of the first electrode 101, the larger the area of the portion where the electric field is likely to concentrate, and thus the metal bridge is likely to be formed.

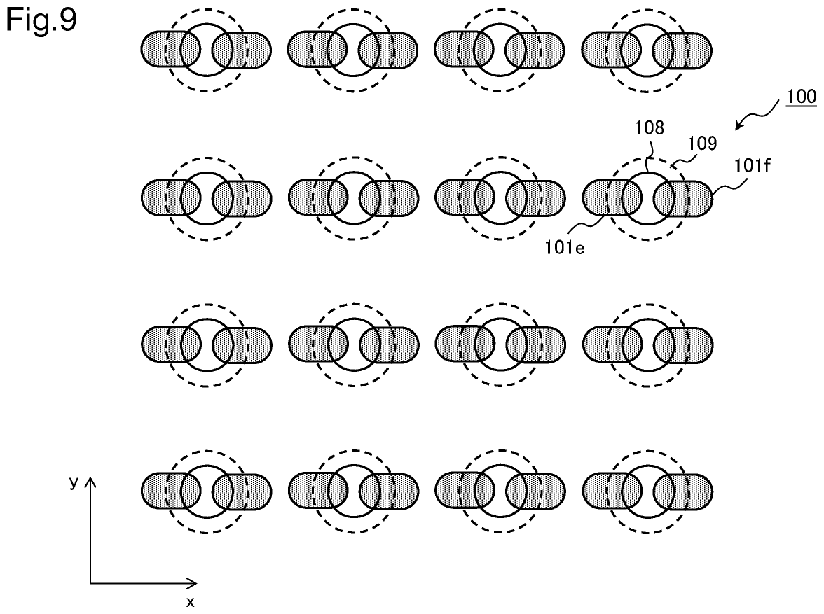

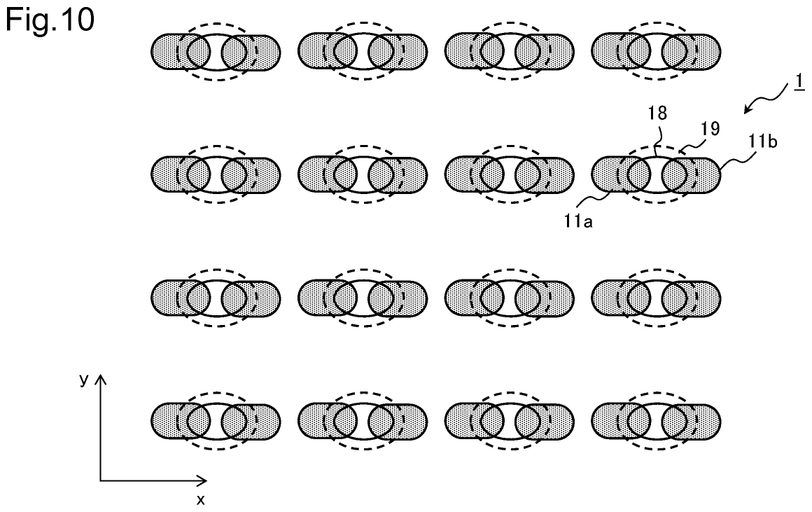

Here, examples of configuring crossbars by arranging the semiconductor devices 100 of the related art and the semiconductor devices 1 of the present example embodiment on substrates in an array form will be described with reference to the drawings. FIG. 9 is a conceptual diagram for explaining an example of configuring a crossbar by arranging the semiconductor devices 100 of the related art on a substrate in an array form. FIG. 10 is a conceptual diagram for explaining an example of configuring a crossbar by arranging the semiconductor devices 1 of the present example embodiment on a substrate in an array form.

In FIGS. 9 and 10, semiconductor devices disposed in the same row are connected to each other by a first wiring (not illustrated) extending in a first direction (x-axis direction). Likewise, semiconductor devices disposed in the same column are connected to each other by a second wiring (not illustrated) extending in a second direction (y-axis direction). The first electrode of each semiconductor device is electrically connected to the first wiring, and the second electrode of each semiconductor device is electrically connected to the second wiring. Semiconductor devices adjacent to each other are disposed at a predetermined interval interposed therebetween.

Comparing the arrangement of the semiconductor devices of the related art in FIG. 9 with the arrangement of the semiconductor devices 1 of the present example embodiment in FIG. 10, the semiconductor devices of the present example embodiment can be disposed in a compressed manner in the y-axis direction. That is, according to the present example embodiment, by lengthening the shapes of the opening 18 and the second electrode region 19, an area for disposing the crossbar constituted by a plurality of semiconductor devices can be reduced.

Here, a difference between the related art and the present example embodiment in raising the density to dispose a plurality of semiconductor devices will be described with reference to the drawings.

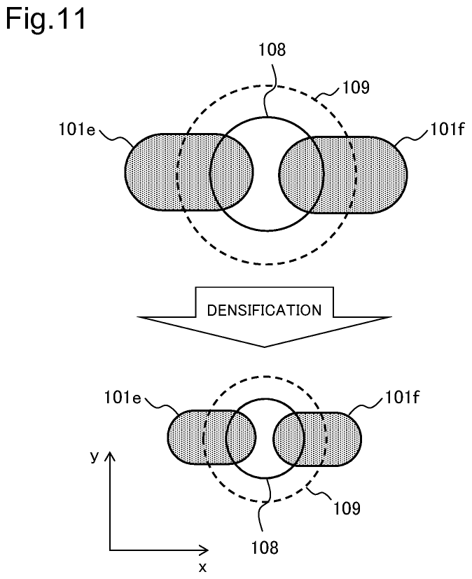

FIG. 11 is a conceptual diagram for explaining an example of raising the density to dispose the semiconductor devices 100 according to the related art. In the related art, when the density to dispose the semiconductor devices 100 is raised, the element size is supposed to be reduced as a whole. Therefore, an expensive exposure apparatus capable of performing finer exposure is required, and the manufacturing cost is increased to fabricate a mask that supports fine exposure. In the semiconductor device 100 of the related art, since the edge exposed lengths of the first electrodes 101e and 101f are decreased for the purpose of densification, there is a concern about degradation in characteristics, such as an expansion in the switching voltage.

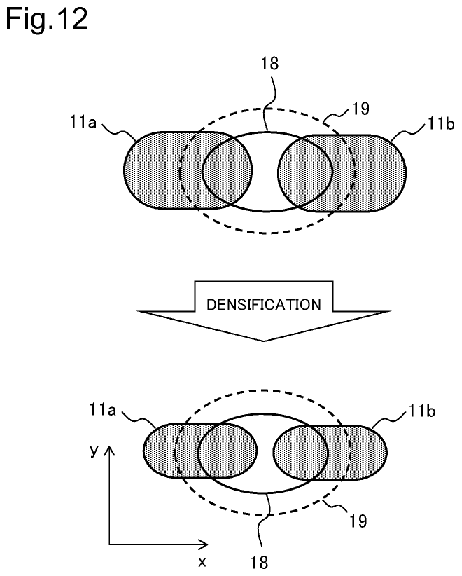

FIG. 12 is a conceptual diagram for explaining an example of raising the density to dispose the semiconductor devices 1 according to the present example embodiment. In the present example embodiment, when the density to dispose the semiconductor devices is raised, since it is not necessary to reduce the element size as a whole, an expensive exposure apparatus capable of performing fine exposure is not required, and the manufacturing cost is not increased due to the fabrication of a mask that supports fine exposure. That is, according to the present example embodiment, the semiconductor devices 1 can be densified at low cost. In the present example embodiment, since the edge exposed length of the first electrode 11 can be expanded when an expensive exposure apparatus capable of performing finer exposure is used, there is no disadvantage of degradation such as an expansion in the switching voltage.

As described above, the semiconductor device of the present example embodiment includes the first insulation layer, the second insulation layer, the first electrode, the variable-resistance layer, and the second electrode. The second insulation layer is disposed on the first insulation layer and has an opening on an upper surface of the second insulation layer. The first electrode is embedded in the second insulation layer, and an end is exposed at the opening. The variable-resistance layer is disposed on the first electrode and the second insulation layer in at least one region from among an inside or a periphery of the opening. The second electrode is disposed on the variable-resistance layer. Then, the opening and the second electrode are formed in a shape stretched in at least one axial direction.

For example, the semiconductor device of the present example embodiment has a shape in which at least one of the opening formation region and the opening region of the second electrode is inscribed in a rectangle. For example, in the semiconductor device of the present example embodiment, at least one of the opening formation region and the opening region of the second electrode is elliptical. For example, in the semiconductor device of the present example embodiment, at least one of the opening formation region and the opening region of the second electrode is rectangular.

For example, the semiconductor device of the present example embodiment includes two first electrodes disposed to face each other with an interval interposed therebetween.

For example, in the semiconductor device of the present example embodiment, the opening and the second electrode are formed in shapes stretched in the same direction, and the second electrode formation region includes the opening region of the opening. For example, in the semiconductor device of the present example embodiment, the first electrode is formed in a shape stretched in one axial direction, and the major axis direction of the first electrode coincides with the major axis directions of the opening and the second electrode. For example, the first electrode is formed in a shape stretched in one axial direction, and the major axis direction of the first electrode coincides with the minor axis directions of the opening and the second electrode.

For example, the semiconductor device of the present example embodiment includes the first wiring extending in the first direction and the second wiring extending in the second direction. For example, the first electrode is formed at an end of the first wiring. For example, the second electrode is electrically connected to the second wiring. For example, the first wiring and the second wiring are copper wirings.

That is, according to the present example embodiment, it is possible to provide a switching element that has been miniaturized without an increase in manufacturing cost and for which a switching voltage variation increase accompanied by miniaturization has been suppressed.

The switching element of the present example embodiment can be utilized as a nonvolatile switching element. In particular, the switching element of the present example embodiment is suitable as a nonvolatile switching element constituting an electronic device such as programmable logic equipment and a memory.

### Second Example Embodiment

Next, a semiconductor device according to a second example embodiment of the present invention will be described with reference to the drawings. The semiconductor device of the present example embodiment illustrates the semiconductor device of the first example embodiment in a more feasible mode. The semiconductor device of the present example embodiment includes a three-terminal type switching element (also called a three-terminal switch).

FIG. 13 is a cross-sectional view illustrating an example of the configuration of a semiconductor device 2 according to the present example embodiment. As illustrated in FIG. 13, the semiconductor device 2 includes a substrate 200, a switching element 20, an insulating laminate 21, and a multilayer wiring layer 22. In the following description, in order to distinguish between multiple individual components, an alphabet character will be sometimes given at the end of the reference sign indicating the component. In a case where multiple individual components are not distinguished, the alphabet character for distinguishing between multiple components will be sometimes omitted.

The substrate 200 is a substrate on which a semiconductor element is formed. For the substrate 200, for example, a substrate such as a silicon substrate, a single crystal substrate, a silicon-on-insulator (SOI) substrate, a thin film transistor (TFT) substrate, or a substrate for liquid crystal manufacturing can be used. The switching element 20, the insulating laminate 21, and the multilayer wiring layer 22 are formed above the substrate 200.

The switching element 20 is a three-terminal type switching element (hereinafter referred to as three-terminal switch) formed inside the insulating laminate 21. The switching element 20 shares some components with the multilayer wiring layer 22. The switching element 20 includes a first electrode 201, a second electrode 202, a variable-resistance layer 203, and a hard mask layer 204. The first electrode 201 includes a first electrode 201a and a first electrode 201b. The second electrode 202 includes a lower second electrode 202a and an upper second electrode 202b. The variable-resistance layer 203 includes a first variable-resistance layer 203a and a second variable-resistance layer 203b. The hard mask layer 204 includes a first hard mask layer 204a and a second hard mask layer 204b.

The insulating laminate 21 is an insulation layer in which the switching element 20 and the multilayer wiring layer 22 are formed. The insulating laminate 21 includes an interlayer insulation layer 211, a Low-k layer 212, an interlayer insulation layer 213, a barrier insulation layer 214, a protective insulation layer 215, an interlayer insulation layer 216, a Low-k layer 217, an interlayer insulation layer 218, and a barrier insulation layer 219. The interlayer insulation layer 211, the Low-k layer 212, and the interlayer insulation layer 213 correspond to a first insulation layer. The barrier insulation layer 214 corresponds to a second insulation layer. The interlayer insulation layer 216, the Low-k layer 217, and the interlayer insulation layer 218 correspond to a third insulation layer.

An opening 28 is formed in the barrier insulation layer 214 as in the first example embodiment. The opening 28 is made in such a way as to taper toward a depth direction (−Z direction). The opening 28 also spreads to parts of the interlayer insulation layer 213 and the first electrode 201. The circumferential edge of the opening 28 made in the barrier insulation layer 214, the interlayer insulation layer 213, and the first electrode 201 forms a tapered surface that tapers toward the depth direction. When the semiconductor device 2 is viewed from the viewpoint on an upper surface side, a region where the second electrode 202 is formed is called a second electrode region 29.

The multilayer wiring layer 22 is a wiring layer formed inside the insulating laminate 21. The multilayer wiring layer 22 includes a first wiring 221, a first barrier metal 222, a second barrier metal 223, a second wiring 224, and a via 225. A portion of the first wiring 221 in contact with the variable-resistance layer 203 denotes the first electrode 201. The first wiring 221 includes a first wiring 221a, a first wiring 221b, and a first wiring 221c. The first barrier metal 222 includes a first barrier metal 222a, a first barrier metal 222b, and a first barrier metal 222c. The second barrier metal 223 includes a second barrier metal 223a and a second barrier metal 223b. The second wiring 224 includes a second wiring 224a and a second wiring 224b. The via 225 includes a via 225a and a via 225b.

The details of each of the switching element 20, the insulating laminate 21, and the multilayer wiring layer 22 will be described below.

[Switching Element]

First, the switching element 20 will be described with reference to FIG. 13.

[First Electrode]

The first electrode 201 is a part of the first wiring 221. A portion of the first wiring 221 exposed at the opening 28 in the barrier insulation layer 214 and in contact with the variable-resistance layer 203 constitutes the first electrode 201. In the example in FIG. 13, a part of the first wiring 221 is dug down, and an upper surface and a side surface (tapered surface) of the dug-down portion constitute the first electrode 201. An upper surface portion of the first wiring 221 that is not dug down is covered with the barrier insulation layer 214. The switching element 20 in FIG. 13 is a three-terminal switch constituting two first electrodes 201 (the first electrode 201a and the first electrode 201b) with respect to one second electrode 202.

[Second Electrode]

The second electrode 202 is formed on an upper surface of the variable-resistance layer 203. A side surface of the second electrode 202 and an upper surface of a circumferential edge portion of the second electrode 202 are covered with the protective insulation layer 215. When the semiconductor device 2 is viewed from the viewpoint on the upper surface side, a region where the second electrode 202 is formed denotes the second electrode region 29. The second electrode 202 includes the lower second electrode 202a and the upper second electrode 202b.

The lower second electrode 202a is formed on an upper surface of the variable-resistance layer 203. The upper second electrode 202b is formed on an upper surface of the lower second electrode 202a. A side surface of the lower second electrode 202a is covered with the protective insulation layer 215.

The lower second electrode 202a is an electrode on a lower layer side of an upper electrode of the switching element 20, and a lower surface of the lower second electrode 202a is in contact with the second variable-resistance layer 203b. For the lower second electrode 202a, an alloy including a metal that is harder to ionize than a metal constituting the first wiring 221 and is hard to diffuse or conduct ions in the second variable-resistance layer 203b, and a metal having good adhesion to a metal constituting the first wiring 221 is used. For example, ruthenium is cited as a metal that is harder to ionize than a metal constituting the first wiring 221 and is hard to diffuse or conduct ions in the second variable-resistance layer 203b. For example, metals such as titanium, tantalum, zirconium, hafnium, and aluminum can be cited as a metal having good adhesion to a metal constituting the first wiring 221. In particular, it is preferable to use a ruthenium alloy for the lower second electrode 202a.

In a case where the lower second electrode 202a is constituted by the ruthenium alloy, it is desirable to select, as an additive metal to be added to ruthenium, a metal having a larger standard Gibbs energy of formation in the negative direction than ruthenium in the course of being oxidized (also called an oxidation course). Titanium, tantalum, zirconium, hafnium, and aluminum, whose standard Gibbs energy of formation in the oxidation course is larger in the negative direction than ruthenium, have high reactivity than ruthenium because these metals demonstrate that chemical reactions are more likely to occur spontaneously. Therefore, in the ruthenium alloy constituting the lower second electrode 202a, the adhesion to a metal bridge formed by a metal constituting the first wirings 221a and 221b is enhanced. On the other hand, when the lower second electrode 202a is constituted by only an additive metal containing no ruthenium, such as titanium, tantalum, zirconium, hafnium, or aluminum, the reactivity is heightened, and thus the switching element 20 no longer transits to the off-state. The transition from the on-state to the off-state proceeds in line with the oxidation reaction (dissolution reaction) of a metal constituting the metal bridge. When the standard Gibbs energy of formation of the oxidation process of a metal constituting the lower second electrode 202a is larger than a metal constituting the first electrode 201 in the negative direction, the oxidation reaction of the lower second electrode 202a proceeds rather than the oxidation reaction of the metal bridge formed by a metal constituting the first wiring 221. Therefore, the switching element 20 cannot transit to the off-state. That is, the metal material used for forming the lower second electrode 202a needs to be an alloy with ruthenium, which has a smaller standard Gibbs energy of formation in the oxidation course than copper in the negative direction. If a component of the metal bridge (copper) is mixed into the lower second electrode 202a, the effect of adding a metal having a larger standard Gibbs energy in the negative direction is weakened. Therefore, the metal added to ruthenium is preferably a material having a barrier property against copper and copper ions. For example, tantalum and titanium have a barrier property against copper and copper ions. Meanwhile, the larger the amount of the additive metal, the more stable the on-state of the switching element 20. Even when an additive metal of about five atomic percent is added, the stability of the on-state of the switching element 20 is enhanced in some cases. In particular, when titanium is used as the additive metal, the transition to the off-state and the stability of the on-state are excellent. In particular, it is preferable that an alloy of ruthenium and titanium are used for the lower second electrode 202a, and the content ratio of titanium fall within the range of 20 to 30 atomic percent. The content ratio of ruthenium in the above ruthenium alloy is desirably equal to or more than 60 atomic percent but equal to or less than 90 atomic percent.

The lower second electrode 202a can be formed using a sputtering method. For example, as a method of forming a film of alloy using a sputtering method, there are a method using an alloy target of ruthenium and an additive metal, and a co-sputtering method in which a ruthenium target and an additive metal target are sputtered simultaneously in the same chamber. For example, as a method for forming a film of alloy using a sputtering method, there is an intermixing method in which a thin film of an additive metal is formed in advance, and ruthenium is formed as a film on the thin film using a sputtering method and is alloyed by the energy of collision atoms. The composition of the alloy can be adjusted when the co-sputtering method and the intermixing method are used. When the intermixing method is adopted, it is preferable to apply heat treatment at 400° C. or lower to smooth the mixed state after the formation of the ruthenium film is completed.

The upper second electrode 202b is an electrode on an upper layer side of the upper electrode of the switching element 20, and is formed on an upper surface of the lower second electrode 202a. A side surface of the upper second electrode 202b and an upper surface of a circumferential edge portion of the upper second electrode 202b are covered with the protective insulation layer 215.

The upper second electrode 202b has a function of protecting the lower second electrode 202a. Since the upper second electrode 202b protects the lower second electrode 202a, damage to the lower second electrode 202a in the manufacturing process for the semiconductor device 2 can be suppressed, and the switching characteristics of the switching element 20 can be maintained. For example, tantalum, titanium, tungsten, or nitrides of these metals, or the like can be used for the upper second electrode 202b. The upper second electrode 202b also functions as an etching stop film when the via 225a is electrically connected to the lower second electrode 202a. Therefore, the upper second electrode 202b is preferably constituted by a material having a low etching rate with respect to a fluorocarbon-based gas plasma used for etching the interlayer insulation layer 216.

For example, the upper second electrode 202b functions as an etching stop film, and is preferably constituted by a nitride of titanium, tantalum, zirconium, hafnium, aluminum or the like having conductivity. When a metal other than the nitride is used for the upper second electrode 202b, a part of a metal constituting the upper second electrode 202b may diffuse into the lower second electrode 202a due to heating or plasma damage during the process. When a part of a metal constituting the upper second electrode 202b diffuses into the lower second electrode 202a, defects are produced inside the lower second electrode 202a, and the dielectric breakdown voltage of the variable-resistance layer 203 may be lowered from these defects as starting points. By using an electrically conductive and stable metal nitride for the upper second electrode 202b, diffusion of the metal to the lower second electrode 202a can be avoided. If the metal as the nitride constituting the upper second electrode 202b, and the additive metal forming an alloy with ruthenium constituting the lower second electrode 202a are the same, a failure due to diffusion of a metal forming an alloy with ruthenium may be reduced more efficiently.

For example, when the lower second electrode 202a is an alloy electrode of ruthenium and titanium, the upper second electrode 202b is preferably a titanium nitride electrode. When the lower second electrode 202a has an alloy of ruthenium and tantalum, the upper second electrode 202b is preferably a tantalum nitride electrode. If metal components constituting the lower second electrode 202a and the upper second electrode 202b are made to coincide with each other, defects are less likely to be formed even if the metal of the upper second electrode 202b diffuses to the lower second electrode 202a. At this time, it is preferable to configure in such a way that the proportion of the metal to the nitrogen of a nitride constituting the upper second electrode 202b is larger than the proportion of the metal to the ruthenium in a ruthenium alloy constituting the lower second electrode 202a. With this configuration, since a metal constituting the lower second electrode 202a is less likely to diffuse to the nitride constituting the upper second electrode 202b, the composition of the ruthenium alloy constituting the lower second electrode 202a may prevent from changing. Specifically, the content ratio of titanium is more preferably equal to or more than 60 atomic percent but equal to or less than 80 atomic percent.

For example, the upper second electrode 202b can be formed using a sputtering method. When a metal nitride film is formed using a sputtering method, it is preferable to use a reactive sputtering method in which a metal target is evaporated using a plasma of a mixed gas of nitrogen and argon. A metal evaporated from the metal target reacts with nitrogen to produce a metal nitride, and is formed as a film.

[Variable-Resistance Layer]

The variable-resistance layer 203 is formed inside and in a peripheral portion of the opening 28 in the barrier insulation layer 214. The second electrode 202 is formed on an upper surface of the variable-resistance layer 203. The variable-resistance layer 203 is formed in the opening 28 on a part of upper surfaces of the interlayer insulation layer 213, the first electrode 201, and the first barrier metal 222, a part of a side surface of the first barrier metal 222, and tapered surfaces of the first electrode 201 and the barrier insulation layer 214. The variable-resistance layer 203 is also formed on an upper surface of the barrier insulation layer 214 at the peripheral portion of the opening 28. The variable-resistance layer 203 is formed within the range of the second electrode region 29.

The variable-resistance layer 203 is a film in which the electrical resistance changes by applying a voltage between the first electrode 201 and the second electrode 202. For the variable-resistance layer 203, a material whose electrical resistance changes depending on actions such as diffusion or ion conduction of metal ions generated from a metal constituting the first wirings 221a and 221b can be used. For example, when the change of the resistance of the switching element 20 accompanied by switching to the on-state is performed by precipitation of metal caused by reduction of metal ions, a film capable of conducting ions is used for the variable-resistance layer 203. The variable-resistance layer 203 includes the first variable-resistance layer 203a and the second variable-resistance layer 203b.

The first variable-resistance layer 203a is formed inside and in a peripheral portion of the opening 28 in the barrier insulation layer 214. The second variable-resistance layer 203b is formed on an upper surface of the first variable-resistance layer 203a. The first variable-resistance layer 203a is formed in the opening 28 on a part of upper surfaces of the interlayer insulation layer 213, the first electrode 201, and the first barrier metal 222, a part of a side surface of the first barrier metal 222, and tapered surfaces of the first electrode 201 and the barrier insulation layer 214. The first variable-resistance layer 203a is also formed on an upper surface of the barrier insulation layer 214 at the peripheral portion of the opening 28. The first variable-resistance layer 203a is formed within the range of the second electrode region 29.

The first variable-resistance layer 203a prevents metals constituting the first wirings 221a and 221b from diffusing into the second variable-resistance layer 203b due to heating or plasma during the deposition of the second variable-resistance layer 203b. The first variable-resistance layer 203a prevents the first wirings 221a and 221b from being oxidized and constituent metals of the first wirings 221a and 221b from being easily diffused to the second variable-resistance layer 203b.

For example, the first variable-resistance layer 203a can be constituted by an oxide of a metal such as zirconium, hafnium, indium, lanthanum, manganese, molybdenum, niobium, tungsten, titanium, and aluminum. These metal oxides can be stably formed without undergoing interfacial reaction with the first electrodes 201a and 201b, the second variable-resistance layer 203b, and the lower second electrode 202a, and can effectively suppress humidity absorption of the second variable-resistance layer 203b. These oxides also have good affinity with general semiconductor manufacturing processes.

For example, the first variable-resistance layer 203a can be formed by forming a film of a metal for constituting the first variable-resistance layer 203a and then oxidizing the formed film in a film formation chamber of the second variable-resistance layer 203b by exposure to an oxygen atmosphere under reduced pressure. The optimum thickness of the metal film constituting the first variable-resistance layer 203a is 0.5 to 1 nanometer. The metal film used for forming the first variable-resistance layer 203a may form a laminated layer or may be configured as a single layer. The first variable-resistance layer 203a can be formed as a film by sputtering. Metal atoms or ions that have obtained energy by sputtering rush into the first wirings 221a and 221b and diffuse to form an alloy layer.

The second variable-resistance layer 203b is formed on an upper surface of the first variable-resistance layer 203a. The lower second electrode 202a is formed on an upper surface of the second variable-resistance layer 203b. The second variable-resistance layer 203b can be constituted by a material containing at least one of tantalum Ta, nickel Ni, titanium Ti, zirconium Zr, hafnium Hf, silicon Si, aluminum Al, iron Fe, vanadium V, manganese Mn, cobalt Co, and tungsten W. For the second variable-resistance layer 203b, a metal oxide film including these elements, a low-dielectric-constant carbon-added silicon oxide film (SiOCH film), a chalcogenide film, a laminated film of the above films, or the like can be applied.

The second variable-resistance layer 203b can be formed using a plasma chemical vapor deposition (CVD) method. For example, when the second variable-resistance layer 203b is formed by the plasma CVD method, the raw material of cyclic organosiloxane and helium, which is a carrier gas, are flowed into a reaction chamber, and the supply of these two types of substances is stabilized. Then, when the pressure in the reaction chamber becomes constant, the application of radio frequency (RF) power is started. For example, the raw material is supplied at 10 to 200 standard cubic centimeters per minute (sccm) and helium is supplied at 500 sccm by way of a raw material vaporizer.

[Hard Mask Layer]

The hard mask layer 204 is a film serving as both of a hard mask film and a passivation film when etching the lower second electrode 202a, the upper second electrode 202b, the first variable-resistance layer 203a, and the second variable-resistance layer 203b. For example, a silicon nitride film, a silicon oxide film, a laminated layer of the above films, or the like can be used for the hard mask layer 204. The hard mask layer 204 preferably includes the same material as the material of the barrier insulation layer 214 and the protective insulation layer 215. If the hard mask layer 204, the barrier insulation layer 214, and the protective insulation layer 215 are constituted by the same material, the material interface can be integrated by enclosing the entire circumference of the switching element 20 with the same material. If the material interface can be integrated, infiltration of moisture and the like from the outside can be avoided, and conversely, desorption from the switching element 20 can also be avoided. The hard mask layer 204 is a mask used in manufacturing the switching element 20. The hard mask layer 204 includes the first hard mask layer 204a and the second hard mask layer 204b. The first hard mask layer 204a and the second hard mask layer 204b may not be included in the configuration of the switching element 20.

The first hard mask layer 204a is a layer used as a mask when the switching element 20 is formed. The first hard mask layer 204a preferably has the same material as the protective insulation layer 215 and the barrier insulation layer 214. By enclosing the entire circumference of the switching element 20 with the same material to thereby integrate the material interface, infiltration of moisture and the like from the outside can be avoided, and conversely, desorption from the switching element 20 can also be avoided.

The first hard mask layer 204a can be formed as a film by the plasma CVD method. For example, a high-density silicon nitride film can be formed by placing a mixed gas of SiH₄/N₂ in a high-density plasma state and subjecting the mixed gas to vapor deposition.

The second hard mask layer 204b is a layer used as a mask when the switching element 20 is formed. The second hard mask layer 204b is preferably a different type of film from the first hard mask layer 204a. For example, a silicon nitride film is employed for the first hard mask layer 204a, while a silicon oxide film is employed for the second hard mask layer 204b.

Similar to the first hard mask layer 204a, the second hard mask layer 204b can be formed as a film using the plasma CVD method. The second hard mask layer 204b may be completely removed during etch-back, and is not an essential component of the semiconductor device 2.

[Insulating Laminate]

Next, the insulating laminate 21 will be described with reference to FIG. 13.

The interlayer insulation layer 211 is an insulating film formed on an upper surface of the substrate 200. For example, a silicon oxide film (SiO film), a carbon-added silicon oxide film (SiOC film), or the like can be used for the interlayer insulation layer 211. The interlayer insulation layer 211 may be obtained by laminating a plurality of insulating films.

The Low-k layer 212 (also called a low-dielectric-constant interlayer insulation layer) is formed between the interlayer insulation layers 211 and 213. The Low-k layer 212 is a low-dielectric-constant film having a lower relative dielectric constant than a silicon oxide film. For example, a low-dielectric-constant carbon-added silicon oxide film (SiOCH film) or the like can be used for the Low-k layer 212. Wiring grooves for embedding the first wirings 221a, 221b, and 221c are formed in the Low-k layer 212. The first barrier metals 222a, 222b, and 222c are formed in these wiring grooves. The first wirings 221a, 221b, and 221c are embedded in these wiring grooves via the first barrier metals 222a, 222b, and 222c.

The interlayer insulation layer 213 is an insulating film formed on an upper surface of the Low-k layer 212. For example, a silicon oxide film (SiO film), a carbon-added silicon oxide film (SiOC film), or the like can be used for the interlayer insulation layer 213. The interlayer insulation layer 213 may be obtained by laminating a plurality of insulating films. Wiring grooves for embedding the first wirings 221a, 221b, and 221c are formed in the interlayer insulation layer 213. The first barrier metals 222a, 222b, and 222c are formed in these wiring grooves. The first wirings 221a, 221b, and 221c are embedded in these wiring grooves via the first barrier metals 222a, 222b, and 222c. The interlayer insulation layer 213 sandwiched between the first wirings 221a and 221b is dug down deeper in the depth direction (−Z direction) than the dug-down portions of the first wirings 221a and 221b when the dug-down portions of the first wirings 221a and 221b are formed.

The barrier insulation layer 214 is formed on an upper surface of the interlayer insulation layer 213 in which the first wirings 221a, 221b, and 221c are embedded. The barrier insulation layer 214 is an insulating film that prevents oxidation of metals constituting the first wirings 221a, 221b, and 221c, and prevents diffusion of metals constituting the first wirings 221a, 221b, and 221c into the interlayer insulation layer 216. The barrier insulation layer 214 functions as an etching stop layer during working of the upper second electrode 202b, the lower second electrode 202a, and the variable-resistance layer 203. For example, a silicon carbide film, a silicon carbonitride film, a silicon nitride film, and a laminated structure of these films can be used for the barrier insulation layer 214. The barrier insulation layer 214 preferably has the same material as the protective insulation layer 215 and the hard mask layer 204 (first hard mask layer 204a).

The opening 28 is formed in the barrier insulation layer 214. The opening 28 has a tapered surface formed in a tapered shape that tapers toward the depth direction (−Z direction). The switching element 20 is configured in the vicinity of the opening 28 in the barrier insulation layer 214. At the opening region of the opening 28, a part of the first electrodes 201a and 201b, the interlayer insulation layer 213, and a part of upper surfaces and side surfaces of the first barrier metals 222a and 222b are exposed. The switching element 20 is constituted by a laminated structure of the first electrodes 201a and 201b, the lower second electrode 202a, the upper second electrode 202b, the first variable-resistance layer 203a, the second variable-resistance layer 203b, the first hard mask layer 204a, and the second hard mask layer 204b. The switching element 20 is covered with the protective insulation layer 215. The protective insulation layer 215 may be included in the configuration of the switching element 20.

In the opening region of the opening 28 formed in the barrier insulation layer 214, the first electrodes 201a and 201b make direct contact with the first variable-resistance layer 203a. A metal constituting the first variable-resistance layer 203a diffuses to the first electrodes 201a and 201b to form an alloy layer.

In the opening region of the opening 28 formed in the barrier insulation layer 214, the upper second electrode 202b is electrically connected to the via 225a and the upper second electrode 202b via the second barrier metal 223a. Turning on and off the switching element 20 can be controlled by applying a voltage or passing a current. For example, turning on and off the switching element 20 can be controlled by utilizing electrolytic diffusion of metal ions supplied from a metal forming the first wirings 221a and 221b to the first variable-resistance layer 203a and the second variable-resistance layer 203b.

In the opening region of the opening 28 formed in the barrier insulation layer 214, the first wirings 221a and 221b may be dug down in the depth direction. At this time, the interlayer insulation layer 213 sandwiched between the first wirings 221a and 221b is also dug down. A portion of the interlayer insulation layer 213 to be dug down is dug down deeper in the depth direction (−Z direction) than the heights of the dug-down portions of the first wirings 221a and 221b. That is, in the opening region of the opening 28 in the barrier insulation layer 214, the variable-resistance layer 203 is formed with a region with two stages having different heights. The first variable-resistance layer 203a is in contact with upper surfaces of the first electrodes 201a and 201b. The first variable-resistance layer 203a is in contact with a part of upper surfaces and side surfaces of the first barrier metals 222a and 222b. Note that the first wiring 221c and the via 225b are electrically connected to each other not via the switching element 20 but via the second barrier metal 223b.

The opening 28 in the barrier insulation layer 214 is formed in an elliptical shape or a rectangular shape (including a rounded rectangle) having the major axis in the same direction as the long side direction (x-axis direction) of the first wirings 221a and 221b. As a result, the perimeters of the first barrier metals 222a and 222b exposed at the opening 28 are expanded, and the areas of the first electrodes 201a and 201b are expanded. The shape of the opening 28 is desirably such that the ratio of the short side to the long side is equal to or more than 1.4 but equal to or less than 1.8.

The hard mask layer 204, the second electrode 202, and the variable-resistance layer 203 are formed in an elongated shape having the major axis in the same direction as the long side direction (x-axis direction) of the first wirings 221a and 221b in such a way as to spread out above the opening 28. For example, the hard mask layer 204, the second electrode 202, and the variable-resistance layer 203 are formed in an elliptical shape or a rectangular shape as viewed from the viewpoint on the upper surface of the semiconductor device 2. When the opening region of the opening 28 is larger than the hard mask layer 204, the second electrode 202, and the variable-resistance layer 203, the first wirings 221a and 221b, and the first barrier metals 222a and 222b are exposed. Therefore, the hard mask layer 204, the second electrode 202, and the variable-resistance layer 203 are formed in an elliptical shape or a rectangular shape in order to ensure that the opening region of the elliptical shape or the rectangular shape is larger than the opening region of the opening 28 and to attain a reduction in area. For example, the shape of the hard mask layer 204, the second electrode 202, and the variable-resistance layer 203 is desirably such that the ratio of the short side to the long side is equal to or more than 1.4 but equal to or less than 1.8.

The protective insulation layer 215 is an insulating film having a function of protecting the switching element 20 and preventing desorption of oxygen from the second variable-resistance layer 203b at the time of manufacturing the semiconductor device 2. For example, a silicon nitride film, a silicon carbonitride film, or the like can be used for the protective insulation layer 215. The protective insulation layer 215 is preferably constituted by the same material as the material of the hard mask layer 204 and the barrier insulation layer 214. When constituted by the same material, the protective insulation layer 215, the hard mask layer 204, and the barrier insulation layer 214 are integrated to enhance the adhesion in the interfaces, and thus the switching element 20 can be more strongly protected.

The interlayer insulation layer 216 is an insulating film formed on an upper surface of the protective insulation layer 215. For example, a silicon oxide film, a carbon-added silicon oxide film, or the like can be used for the interlayer insulation layer 216. The interlayer insulation layer 216 may be obtained by laminating a plurality of insulating films. The interlayer insulation layer 216 may have the same material as the interlayer insulation layer 218. In the interlayer insulation layer 216, pre-holes for embedding the vias 225a and 225b are formed. The second barrier metals 223a and 223b are formed in these pre-holes. The vias 225a and 225b are embedded in these pre-holes via the second barrier metals 223a and 223b.

The Low-k layer 217 (also called a low-dielectric-constant interlayer insulation layer) is a low-dielectric-constant film that is interposed between the interlayer insulation layers 216 and 218 and has a lower relative dielectric constant than the silicon oxide film. For example, a SiOCH film or the like can be used for the Low-k layer 217. Wiring grooves for embedding the second wirings 224a and 224b are formed in the Low-k layer 217. The second barrier metals 223a and 223b are formed in these wiring grooves. The second wirings 224a and 224b are embedded in these wiring grooves via the second barrier metals 223a and 223b.

The interlayer insulation layer 218 is an insulating film formed on an upper surface of the Low-k layer 217. For example, a silicon oxide film, a SiOC film, a low-dielectric-constant film having a lower relative dielectric constant than the silicon oxide film, or the like is used for the interlayer insulation layer 218. For example, a SiOCH film can be used for the interlayer insulation layer 218. The interlayer insulation layer 218 may be obtained by laminating a plurality of insulating films. The interlayer insulation layer 218 may have the same material as the interlayer insulation layer 216. Wiring grooves for embedding the second wirings 224a and 224b are formed in the interlayer insulation layer 218. The second barrier metals 223a and 223b are formed in these wiring grooves. The second wirings 224a and 224b are embedded in these wiring grooves via the second barrier metals 223a and 223b.

The barrier insulation layer 219 is formed on an upper surface of the interlayer insulation layer 218 including the second wirings 224a and 224b. The barrier insulation layer 219 is an insulating film that prevents oxidation of metals constituting the second wirings 224a and 224b, and prevents diffusion of metals constituting the second wirings 224a and 224b to an upper layer. For example, a silicon carbonitride film, a silicon nitride film, and a laminated structure of these films can be used for the barrier insulation layer 219.

[Multilayer Wiring Layer]

Next, the multilayer wiring layer 22 will be described with reference to FIG. 13.

The first wiring 221 is a wiring embedded in the wiring groove formed in the interlayer insulation layer 213 and the Low-k layer 212 via the first barrier metal 222. For example, the first wiring 221 can be constituted by a metal such as copper. The first wiring 221 includes the first wiring 221a, the first wiring 221b, and the first wiring 221c.

The first wirings 221a and 221b also serve as lower electrodes of the switching element 20. Parts of the first wirings 221a and 221b make contact with the first variable-resistance layer 203a. Portions of the first wirings 221a and 221b in contact with the first variable-resistance layer 203a denote the first electrodes 201a and 201b.

A metal capable of diffusing and conducting ions in the variable-resistance layer 203 is used as a metal constituting the first wiring 221a. For example, a metal including copper can be used for the first wiring 221a. When copper is included, the first wirings 221a and 221b may be alloyed with aluminum.

The first wirings 221a and 221b may be dug down in the depth direction (−Z direction) at the opening 28 in the barrier insulation layer 214. In this case, the first wirings 221a and 221b are in contact with the first variable-resistance layer 203a via the dug-down portions. An alloy layer with a metal constituting the first variable-resistance layer 203a is formed at the interface between the dug-down portions of the first wirings 221a and 221b and the first variable-resistance layer 203a. The alloy layer is not formed on the entire first wirings 221a and 221b, but is formed on the first electrodes 201a and 201b located at the opening 28 in the barrier insulation layer 214. For example, the dug-down portions can be formed by performing plasma etching after forming an opening surface of the barrier insulation layer 214 in contact with the first wirings 221a and 221b. For example, in the plasma etching, a plasma using a halogen gas, an inert gas, a fluorocarbon gas, and a mixed gas of the above gases is injected into the substrate 200 including the first wirings 221a and 221b, and the interlayer insulation layer 213 in a dry etching apparatus. At this time, the barrier insulation layer 214 is also etched, but the first wiring 221c, in which the switching element 20 is not formed, is not dug down because the first wiring 221c is not exposed to the plasma.

By employing parts of the first wirings 221a and 221b as a lower electrode (the first electrodes 201a and 201b) of the switching element 20, it is possible to make the electrode resistance lower while simplifying the number of steps. According to the technique of the present example embodiment, the switching element 20 can be equipped only by creating a mask set of at least two photoresists (PRs) as an additional step to the ordinary copper damascene wiring process. That is, according to the configuration of the present example embodiment, it is possible to simultaneously accomplish a low resistance and a low cost for the element.

The first wiring 221c makes contact with the second barrier metal 223b at the opening in the barrier insulation layer 214. The first wiring 221c is electrically connected to the via 225b and the second wiring 224b via the second barrier metal 223b.

The first barrier metal 222 is a conductive film with barrier properties formed inside the wiring groove formed in the low-k layer 212 and the interlayer insulation layer 213. The first barrier metal 222 covers a side surface and a bottom surface of the first wiring 221. The first barrier metal 222 prevents a metal constituting the first wiring 221 from diffusing to the interlayer insulation layer 213 and a lower layer. For example, when the first wiring 221 is mainly composed of copper, a high melting point metal such as tantalum, tantalum nitride, titanium nitride, and tungsten carbonitride, or a nitride of such a high melting point metal, or a laminated film of the above substances, or the like can be used for the first barrier metal 222. The first barrier metal 222 includes the first barrier metal 222a, the first barrier metal 222b, and the first barrier metal 222c.

The second barrier metal 223 is a conductive film with barrier properties formed inside the wiring groove formed in the barrier insulation layer 214, the protective insulation layer 215, the interlayer insulation layer 216, the Low-k layer 217, and the interlayer insulation layer 218. The second barrier metal 223 covers a side surface and a bottom surface of the via 225 and the second wiring 224. The second barrier metal 223 prevents metals constituting the second wiring 224 and the via 225 from diffusing to the interlayer insulation layer 216, the Low-k layer 217, the interlayer insulation layer 218, and the like. For example, when the via 225 and the second wiring 224 have a metal element mainly composed of copper, a high melting point metal such as tantalum, tantalum nitride, titanium nitride, and tungsten carbonitride, or a nitride of such a high melting point metal, or a laminated film of the above substances, or the like can be used for the second barrier metal 223. The second barrier metal 223 preferably has the same material as the upper second electrode 202b. For example, when the second barrier metal 223 is constituted by a laminated structure of tantalum nitride (lower layer) and tantalum (upper layer), tantalum nitride as a lower layer material is preferably used for the upper second electrode 202b. The second barrier metal 223 includes the second barrier metal 223a and the second barrier metal 223c.

The second wirings 224 are wirings embedded in the wiring grooves formed in the interlayer insulation layer 218 and the Low-k layer 217 via the second barrier metals 223a and 223b. The second wiring 224 is formed integrally with the via 225. For example, the second wiring 224 can be constituted by a metal such as copper. The second wiring 224 includes the second wiring 224a and the second wiring 224b.

The second wiring 224a is a conductor formed integrally with the via 225a. The second wiring 224a is a wiring embedded in the wiring groove formed in the interlayer insulation layer 218 and the Low-k layer 217 via the second barrier metal 223a. The second wiring 224a is electrically connected to the upper second electrode 202b via the via 225a and the second barrier metal 223a.

The second wiring 224b is a conductor formed integrally with the via 225b. The second wiring 224b is a wiring embedded in the wiring groove formed in the interlayer insulation layer 218 and the Low-k layer 217 via the second barrier metal 223b. The second wiring 224b is electrically connected to the first wiring 221c via the via 225b and the second barrier metal 223b.

The via 225 is a conductor formed integrally with the second wiring 224. For example, the via 225 can be constituted by a metal such as copper. The via 225 includes the via 225a and the via 225b.

The via 225a is embedded in the pre-hole formed in the hard mask layer 204, the protective insulation layer 215, and the interlayer insulation layer 216 via the second barrier metal 223a. The via 225a is electrically connected to the upper second electrode 202b via the second barrier metal 223a.

The via 225b is embedded in the pre-hole formed in the barrier insulation layer 214, the protective insulation layer 215, and the interlayer insulation layer 216 via the second barrier metal 223b. The via 225b is electrically connected to the first wiring 221c via the second barrier metal 223b.

The above is the description of the detailed configuration of the semiconductor device 2. The configuration of the semiconductor device 2 described above is merely an example and does not limit the configuration of the semiconductor device 2.

(Manufacturing Method)

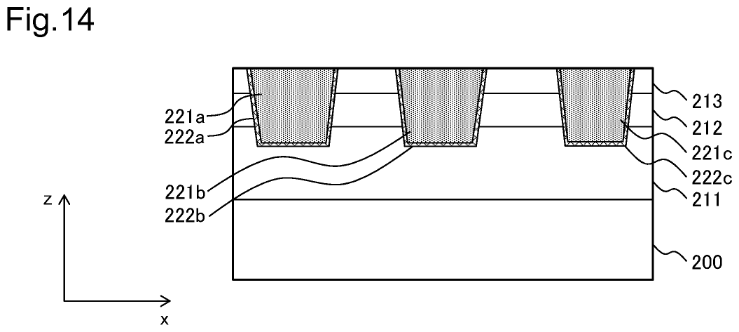

Next, an example of a method of manufacturing the semiconductor device 2 will be described with reference to the drawings. FIGS. 14 to 25 are cross-sectional views for explaining the method of manufacturing the semiconductor device 2 (steps 1 to 12). In the method of manufacturing the semiconductor device 2 illustrated in FIGS. 14 to 25 (steps 1 to 12), some steps are omitted.

[Step 1]

FIG. 14 is a conceptual diagram for explaining step 1 of the method of manufacturing the semiconductor device 2. In step 1, the interlayer insulation layer 211, the Low-k layer 212, and the interlayer insulation layer 213 are sequentially laminated on the substrate 200 on which the semiconductor element is formed. For example, the interlayer insulation layers 211 and 213 can be formed by the plasma chemical vapor deposition (CVD) method.

For example, a silicon oxide film having a thickness of 500 nanometers is formed on the substrate 200 as the interlayer insulation layer 211. Next, a SiOCH film having a thickness of 150 nanometers is formed on an upper surface of the interlayer insulation layer 211 as the Low-k layer 212. Then, a silicon oxide film having a thickness of 100 nanometers is formed on an upper surface of the Low-k layer 212 as the interlayer insulation layer 213.

Next, the wiring grooves are formed in the interlayer insulation layer 213 and the barrier insulation layer 214 using a lithography method including photoresist formation, dry etching, and photoresist removal. Then, the first barrier metals 222a, 222b, and 222c are formed in the formed wiring grooves.

For example, the first barrier metals 222a, 222b, and 222c can be formed by a physical vapor deposition (PVD) method. For example, the first barrier metals 222a, 222b, and 222c are configured by laminating tantalum nitride having a film thickness of five nanometers on tantalum having a film thickness of five nanometers.

Then, the first wirings 221a, 221b, and 221c are embedded in the above-formed wiring grooves via the first barrier metals 222a, 222b, and 222c. For example, the first wirings 221a, 221b, and 221c are constituted by copper wirings.

For example, copper seeds are formed inside the first barrier metals 222a, 222b, and 222c by the PVD method, and subsequently copper is buried in the wiring grooves by an electrolytic plating method. Then, after heat treatment is processed at a temperature equal to or higher than 200° C., excess copper other than copper inside the wiring grooves is removed by a chemical mechanical polishing (CMP) method, and consequently the first wirings 221a, 221b, and 221c can be formed. The CMP method is a method of planarizing unevenness on the wafer surface produced during the process of forming the multilayer wiring, by polishing the wafer surface by bringing the wafer surface into contact with a polishing pad being rotated while passing a polishing liquid over the wafer surface. In the CMP method, for example, excess copper embedded in the wiring groove is polished away to form an embedded wiring (damascene wiring), and an interlayer insulating film is polished to be planarized.

[Step 2]

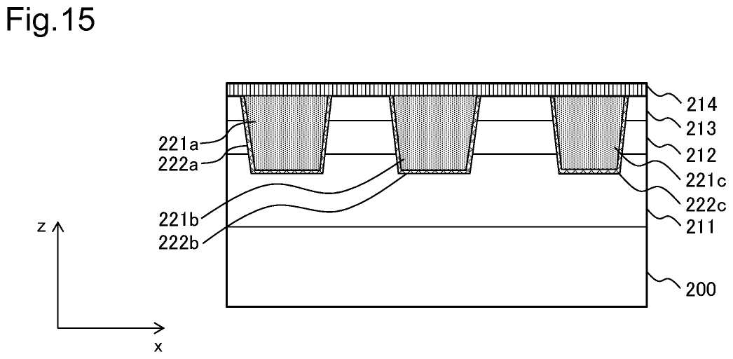

FIG. 15 is a conceptual diagram for explaining step 2 of the method of manufacturing the semiconductor device 2. In step 2, the barrier insulation layer 214 is formed on the interlayer insulation layer 213 including the first wirings 221a, 221b, and 221c. For example, the barrier insulation layer 214 can be formed by the plasma CVD method.

The barrier insulation layer 214 is preferably formed to have a thickness of about 10 to 50 nanometers. For example, a silicon nitride film or a silicon carbonitride film having a thickness of 30 nanometers is formed as the barrier insulation layer 214.

[Step 3]

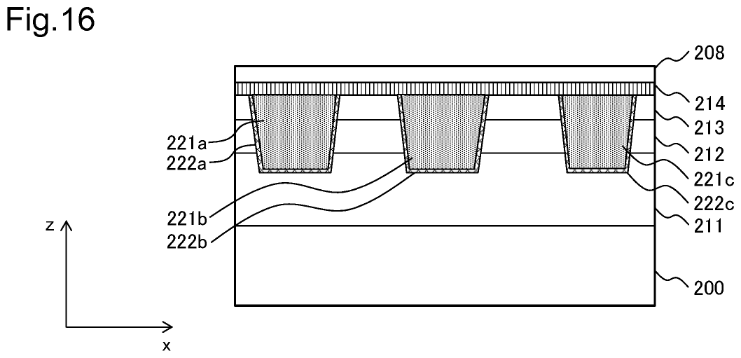

FIG. 16 is a conceptual diagram for explaining step 3 of the method of manufacturing the semiconductor device 2. In step 3, a hard mask film 208 is formed on an upper surface of the barrier insulation layer 214. The hard mask film 208 preferably has a material different from the material of the barrier insulation layer 214 in view of keeping a large etching selectivity in the dry etching working, and may be an insulating film or a conducting film.

For example, a silicon oxide film, a silicon nitride film, titanium nitride, titanium, tantalum, tantalum nitride, or the like can be used for the hard mask film 208. A laminate of silicon nitride and a silicon oxide film can be used as the hard mask film 208. For example, a silicon oxide film having a thickness of 40 nanometers is formed as the hard mask film 208.

[Step 4]

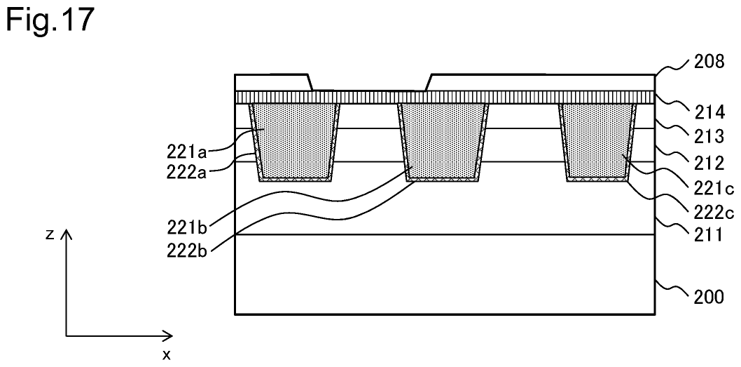

FIG. 17 is a conceptual diagram for explaining step 4 of the method of manufacturing the semiconductor device 2. In step 4, an opening is patterned on the hard mask film 208 using a photoresist (not illustrated), and dry etching is performed using the photoresist as a mask to form an opening pattern in the hard mask film 208. Thereafter, the photoresist is stripped by oxygen plasma ashing or the like. At this time, the dry etching need not be stopped on the upper surface of the barrier insulation layer 214, and may reach the inside of the barrier insulation layer 214.

The shape of the photoresist is an ellipse or a rectangle whose long side direction is oriented in the same orientation as the long side direction of the first wirings 221a and 221b. At this time, the hard mask film 208 is also worked into the same shape as the shape of the photoresist.

[Step 5]

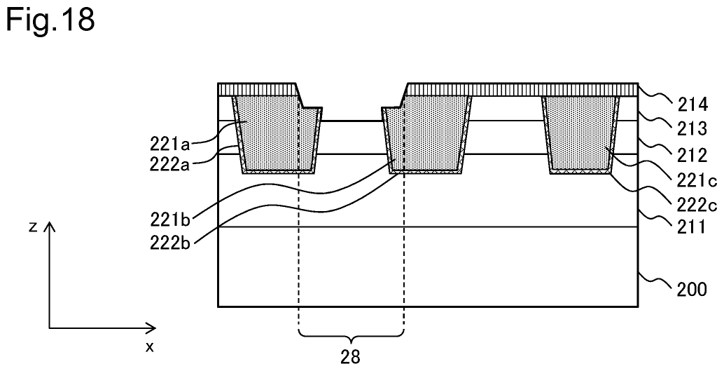

FIG. 18 is a conceptual diagram for explaining step 5 of the method of manufacturing the semiconductor device 2. In step 5, the barrier insulation layer 214 exposed at the opening of the hard mask film 208 is etched back (dry etching) using the hard mask film 208 as a mask, and thus the opening 28 is formed in the barrier insulation layer 214. At this time, parts of the first wirings 221a and 221b is exposed at the opening 28 of the barrier insulation layer 214. A mixed gas of fluorocarbon gas, argon, and sometimes oxygen is used for etch-back. Specifically, fluorocarbon and oxygen are of about the same amount, and argon is mixed at a ratio of about 10 to 20 times of fluorocarbon or oxygen.

If reactive dry etching is used when the barrier insulation layer 214 is etched back, an inner side surface of the opening 28 in the barrier insulation layer 214 can be formed in a tapered surface. In the reactive dry etching, a gas containing fluorocarbon is used as an etching gas. The hard mask film 208 is preferably completely removed during etch-back, but may remain in a case where the hard mask film 208 has an insulating material. The shape of the opening 28 in the barrier insulation layer 214 is an ellipse or a rectangle whose long side direction is oriented in the same orientation as the long side direction of the first wirings 221a and 221b. For example, the length of the long side of the opening 28 in the barrier insulation layer 214 is set to 70 to 500 nanometers.

[Step 6]

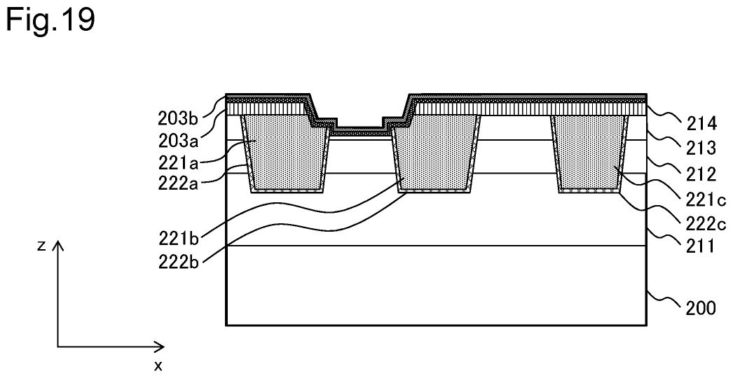

FIG. 19 is a conceptual diagram for explaining step 6 of the method of manufacturing the semiconductor device 2. In step 6, the variable-resistance layer 203 (the first variable-resistance layer 203a and the second variable-resistance layer 203b) is formed on the barrier insulation layer 214 including the first wirings 221a and 221b.

First, zirconium having a thickness of one nanometer is deposited by a sputtering method on the barrier insulation layer 214 including the first wirings 221a and 221b. Zirconium is oxidized when the second variable-resistance layer 203b is formed to become the first variable-resistance layer 203a. For example, zirconium is laminated and subsequently annealed at a temperature of 350° C. under a vacuum environment. The annealing time is preferably about two to ten minutes. When the copper of the first wiring 221 is oxidized, the oxidized copper is spontaneously reduced at a location where the first wiring 221 is in contact with the first variable-resistance layer 203a. This is because the standard Gibbs energy of formation of copper oxide is larger than that of zirconium oxide, and thus oxygen bonded to copper in the first wiring 221 diffuses to a metal constituting the first variable-resistance layer 203a and moves to the zirconium side, which is more easily oxidized.

As the second variable-resistance layer 203b, a SiOCH-based polymer film containing silicon, oxygen, carbon and hydrogen is formed by plasma CVD. The raw material of cyclic organosiloxane and helium, which is a carrier gas, are flowed into a reaction chamber, and when the supply of these two types of substances is stabilized and the pressure in the reaction chamber becomes constant, the application of RF power is started. The raw material of cyclic organosiloxane is supplied at 10 to 200 sccm. Helium is supplied at 500 sccm by way of a raw material vaporizer and also supplied at 500 sccm directly to the reaction chamber on a separate line. Moisture and the like stick to the opening 28 in the barrier insulation layer 214 due to air exposure. Therefore, it is preferable to apply heat treatment under reduced pressure at a temperature of about 250° C. to 350° C. to perform degassing before the deposition of the first variable-resistance layer 203a.

[Step 7]

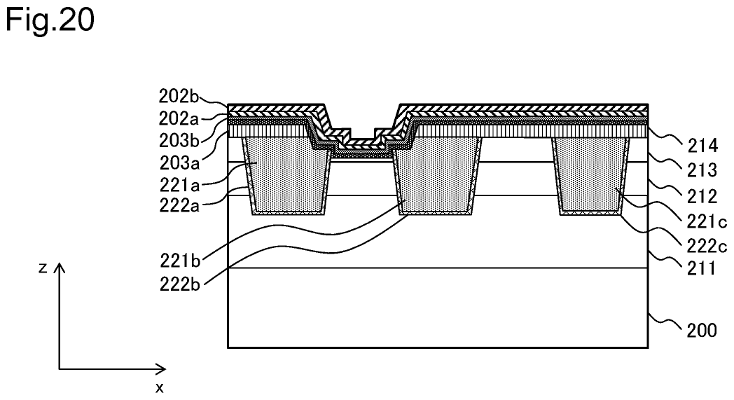

FIG. 20 is a conceptual diagram for explaining step 7 of the method of manufacturing the semiconductor device 2. In step 7, the second electrode 202 (the lower second electrode 202a and the upper second electrode 202b) is formed on an upper surface of the variable-resistance layer 203 (second variable-resistance layer 203b).

First, an alloy of ruthenium and titanium having a film thickness of 10 nanometers is formed as the lower second electrode 202a on an upper surface of the variable-resistance layer 203 by the co-sputtering method. At this time, a ruthenium target and a titanium target are placed in the same chamber, and an alloy film is deposited by simultaneous sputtering. For example, by setting the power applied to the ruthenium target to 150 watts and the power applied to the titanium target to 50 watts, a ruthenium-titanium alloy having a ruthenium content ration of 75 atomic percent can be deposited.

Next, titanium nitride is formed as the upper second electrode 202b to have a film thickness of 25 nanometers on an upper surface of the lower second electrode 202a by a reactive sputtering method. At this time, the power applied to the titanium target is set to 600 watts, and a nitrogen gas and an argon gas are introduced into the chamber to be sputtered. By setting the flow rate of nitrogen and the flow rate of argon to 1:1, the proportion of titanium in titanium nitride can be adjusted to 70 atomic percent.

[Step 8]

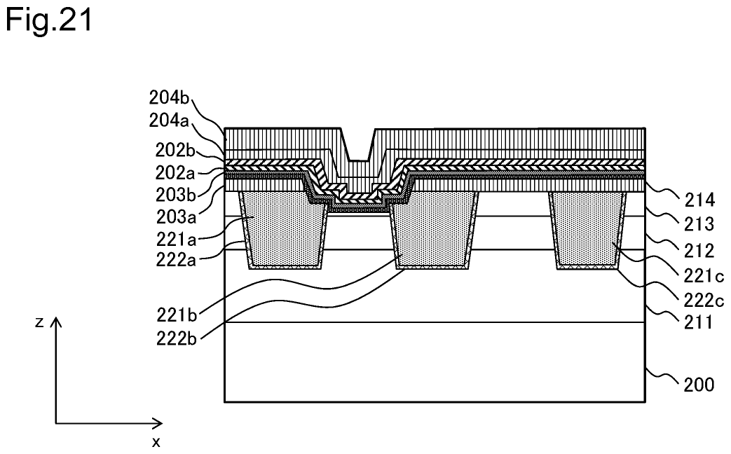

FIG. 21 is a conceptual diagram for explaining step 8 of the method of manufacturing the semiconductor device 2. In step 8, the hard mask layer 204 (the first hard mask layer 204a and the second hard mask layer 204b) is formed on an upper surface of the second electrode 202 (upper second electrode 202b).

First, the first hard mask layer 204a is deposited on an upper surface of the upper second electrode 202b. For example, a silicon nitride film or a silicon carbonitride film having a thickness of 30 nanometers is deposited as the first hard mask layer 204a.

Next, the second hard mask layer 204b is deposited on an upper surface of the first hard mask layer 204a. For example, a silicon oxide film having a thickness of 80 nanometers is deposited as the second hard mask layer 204b.

[Step 9]

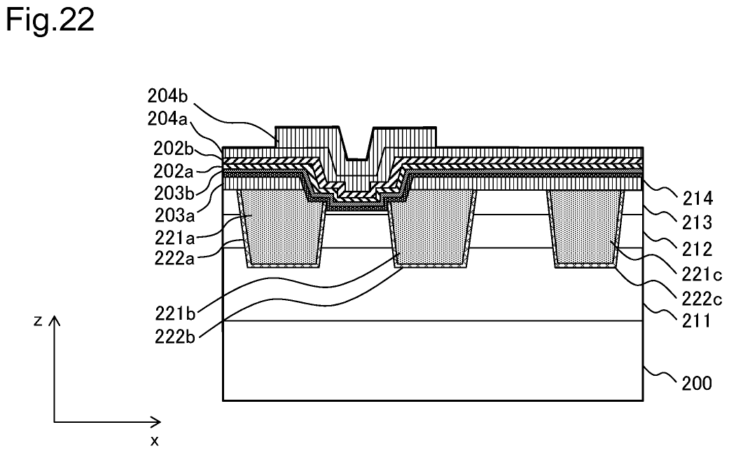

FIG. 22 is a conceptual diagram for explaining step 9 of the method of manufacturing the semiconductor device 2. In step 9, the second hard mask layer 204b is patterned.

First, a photoresist (not illustrated) for patterning the switching element 20 is formed on an upper surface of the second hard mask layer 204b. The shape of the photoresist is an ellipse or a rectangle whose long side direction is oriented in the same orientation as the long side direction of the first wirings 221a and 221b.

Next, the second hard mask layer 204b is dry-etched using the formed photoresist as a mask until the first hard mask layer 204a is exposed.

Next, the photoresist is removed using oxygen plasma ashing and organic stripping. As a result, the second hard mask layer 204b is worked into the same shape as the shape of the photoresist.

[Step 10]

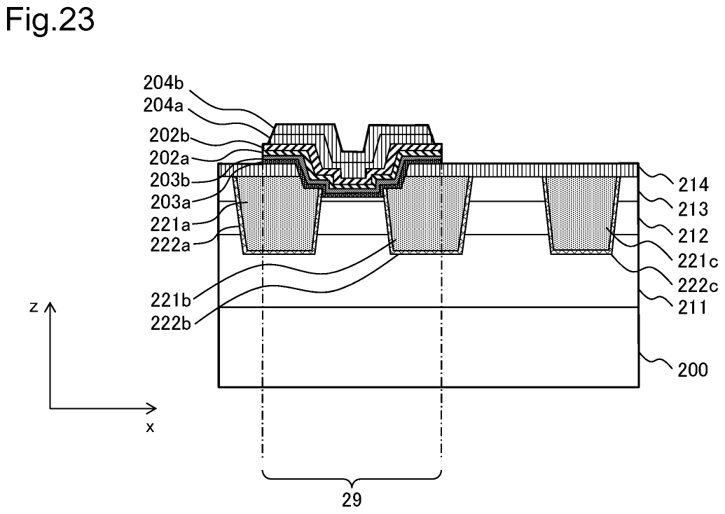

FIG. 23 is a conceptual diagram for explaining step 10 of the method of manufacturing the semiconductor device 2.

Using the second hard mask layer 204b as a mask, the first hard mask layer 204a, the upper second electrode 202b, the lower second electrode 202a, and the variable-resistance layer 203 are dry-etched consecutively. The second hard mask layer 204b is preferably completely removed during etch-back, but may remain intact.

For example, when the upper second electrode 202b has titanium nitride, the upper second electrode 202b can be worked by chlorine-based reactive ion etching (RIE). When the lower second electrode 202a has an alloy of ruthenium and titanium, RIE working is enabled with a chlorine- and oxygen-based mixed gas. In the etching of the variable-resistance layer 203, it is necessary to stop the dry etching on the barrier insulation layer 214 on a lower surface. When the variable-resistance layer 203 is a SiOCH-based polymer film and the barrier insulation layer 214 is a silicon nitride film or a silicon carbonitride film, RIE working is enabled by adapting etching conditions with, for example, a tetrafluoromethane-based, tetrafluoromethane- and chlorine-based, or tetrafluoromethane-, chlorine-, and argon-based mixed gas.

By using the hard mask RIE method as described above, the switching element 20 can be worked without being exposed to oxygen plasma ashing for resist removal. The worked first hard mask layer 204a, upper second electrode 202b, lower second electrode 202a, and variable-resistance layer 203 have the shape of an ellipse or a rectangle whose long side direction is oriented in the same orientation as the long side direction of the first wirings 221a and 221b.

[Step 11]

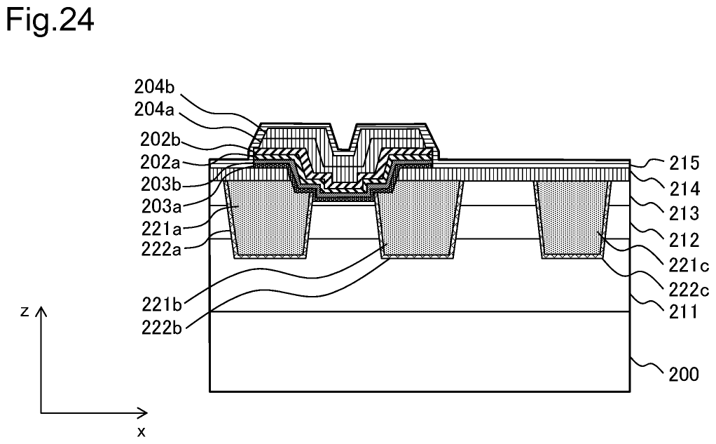

FIG. 24 is a conceptual diagram for explaining step 11 of the method of manufacturing the semiconductor device 2. In step 11, the protective insulation layer 215 is deposited on the barrier insulation layer 214 including the hard mask layer 204, the upper second electrode 202b, the lower second electrode 202a, and the variable-resistance layer 203.

For example, a silicon nitride film or a silicon carbonitride film having a thickness of 20 nanometers is deposited as the protective insulation layer 215 on the barrier insulation layer 214 including the hard mask layer 204, the upper second electrode 202b, the lower second electrode 202a, and the variable-resistance layer 203. The protective insulation layer 215 can be formed by the plasma CVD method. When the plasma CVD method is used, there is a possibility that oxygen is desorbed from a side surface of the variable-resistance layer 203 and the amount of leakage current is expanded in the ion conductive layer while the variable-resistance layer 203 is maintained under reduced pressure in the reaction chamber before film formation. In order to suppress the desorption of oxygen from a side surface of the variable-resistance layer 203, the film-forming temperature of the protective insulation layer 215 is preferably equal to or less than 300° C. Since the exposure to the film forming gas under reduced pressure is expected before film formation, it is preferable not to use a reducing gas. For example, a high-density silicon nitride film obtained by regulating the substrate temperature to 300° C., placing a mixed gas of SiH₄/N₂ in a high-density plasma state, and subjecting the mixed gas to vapor deposition is preferably used for the protective insulation layer 215.

[Step 12]

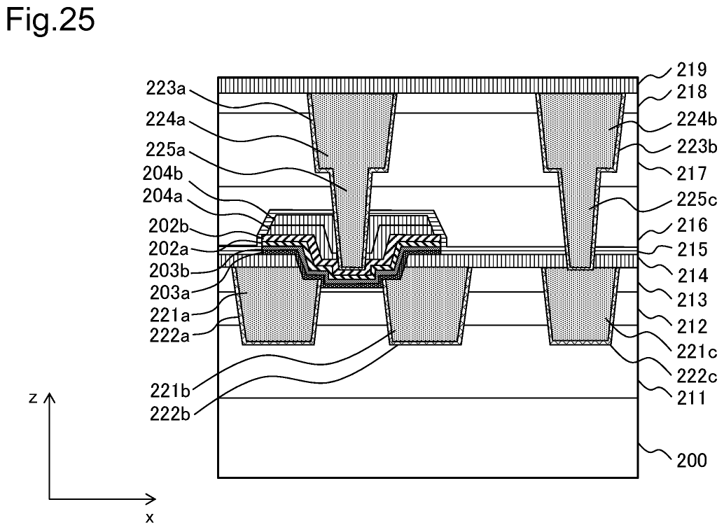

FIG. 25 is a conceptual diagram for explaining step 12 of the method of manufacturing the semiconductor device 2. In step 12, at least one insulation layer is laminated on the protective insulation layer 215, the second wiring 224 and the via 225 are embedded inside the insulation layer, and an uppermost surface is covered with the barrier insulation layer 219.

First, the interlayer insulation layer 216 is deposited on an upper surface of the protective insulation layer 215. For example, a silicon oxide film is deposited as the interlayer insulation layer 216.

Next, the Low-k layer 217 is deposited on an upper surface of the interlayer insulation layer 216. For example, a SiOCH film having a thickness of 150 nanometers is deposited as the Low-k layer 217.

Next, the interlayer insulation layer 218 is deposited on an upper surface of the Low-k layer 217. For example, a silicon oxide film is deposited as the interlayer insulation layer 218.

The interlayer insulation layer 216, the Low-k layer 217, and the interlayer insulation layer 218 can be formed by the plasma CVD method. In order to eliminate a step formed by the switching element 20, a desired film thickness of the interlayer insulation layer 216 may be enabled by depositing the interlayer insulation layer 216 thick, and then grinding and planarizing the interlayer insulation layer 216 by chemical mechanical polishing (CMP).

Next, the wiring grooves for embedding the second wirings 224a and 224b, and the pre-holes for embedding the vias 225a and 225b are formed. The pre-holes for embedding the vias 225a and 225b are formed by being patterned by exposure using the same photomask as for the wiring grooves for embedding the second wirings 224a and 224b, and being simultaneously etched.

Next, the second barrier metals 223a and 223b are formed in the wiring grooves and the pre-holes. For example, tantalum nitride and tantalum are used as the second barrier metals 223a and 223b.

Next, the second wirings 224a and 224b, and the vias 225a and 225b are simultaneously formed in the wiring grooves and the pre-holes via the second barrier metals 223a and 223b. For example, when constituted by copper, the second wirings 224a and 224b, and the vias 225a and 225b can be simultaneously formed using a copper dual damascene wiring process. The second wirings 224a and 224b can be formed using a process similar to the process for the lower layer wiring. At this time, if the same material is employed for the second barrier metal 223a and the upper second electrode 202b, the contact resistance between the second barrier metal 223a and the upper second electrode 202b can be lessened, and the element performance can be enhanced.

Then, the barrier insulation layer 219 is deposited on the interlayer insulation layer 218 including the second wirings 224a and 224b. For example, a silicon nitride film is deposited as the barrier insulation layer 219.

The above is the description of the method of manufacturing the semiconductor device 2. The above description is merely an example and does not limit the method of manufacturing the semiconductor device 2.

As described above, the semiconductor device of the present example embodiment includes the first insulation layer, the second insulation layer, the first wiring, the variable-resistance layer, the second electrode, the third insulation layer, the second wiring, and the via. The second insulation layer is disposed on the first insulation layer and has an opening on an upper surface of the second insulation layer. The first wiring is extended in the first direction and is embedded in the second insulation layer, and at least an end that is exposed at the opening constitutes the first electrode. The variable-resistance layer is disposed on the first wiring and the second insulation layer in at least one region from among an inside or a periphery of the opening. The second electrode is disposed on the variable-resistance layer. The third insulation layer is disposed above the first electrode, the variable-resistance layer, and the second electrode. The second wiring is embedded in the third insulation layer via the barrier metal, and is extended in the second direction that intersects the first direction. The via is embedded in the third insulation layer integrally with the second wiring via the barrier metal, and the opening and the second electrode that are electrically connected to the second electrode via the barrier metal are formed in a shape that is stretched in at least one axial direction.

For example, in the semiconductor device of the present example embodiment, at least one switching cell constituted by the first electrode, the variable-resistance layer, and the second electrode is disposed at a position where the first wiring and the second wiring intersect each other to constitute a crossbar.

In the switching element of the semiconductor device of the present example embodiment, two first electrodes formed on edges of two copper wirings are disposed in series in such a way as to be opposite to each other, and an opening is provided in the insulating film above the two first electrodes. In the switching element of the present example embodiment, when a voltage is applied between the second electrode serving as an upper electrode and the first electrode serving as a lower electrode, the electric field is concentrated in the copper wiring in an edge having a large surface morphology, that is, near the interface between the barrier metal and the copper. The longer the perimeter of this edge, the more locations where the electric field is likely to concentrate, and thus the more locations where the copper bridge is formed. Therefore, when the shape of the opening provided in the insulating film is an elongated shape (an ellipse or rectangle) having the long side in the long side direction of the copper wiring, a length in which the edge of the copper wiring is exposed is expanded, and thus the variation in switching voltage between the elements decreases. At this time, if the second electrode is formed with a minimum area in order to cover the opening at which the copper wiring is exposed with the second electrode, the shape of the second electrode is supposed to be an elongated shape (an ellipse or rectangle) similar to the shape of the opening.

In the present example embodiment, since the shapes of the opening and the second electrode in the insulating film are elliptical or rectangular, the exposure area is enlarged, and accordingly exposure happens easily. Therefore, according to the present example embodiment, it is possible to miniaturize the elongated shape (an ellipse or rectangle) in the short side direction without using latest exposure apparatus and mask.

As described above, according to the present example embodiment, the switching element can be miniaturized without using a high-cost exposure apparatus, mask, or process. According to the present example embodiment, since the exposed portion of the copper wiring where the electric field is concentrated during the switching operation is expanded, a switching element that is excellent in reliability, yield, and performance, and a rewritable semiconductor device using the switching element can be provided. That is, according to the present example embodiment, the switching element can be miniaturized at low cost, and variation in switching voltage can be improved.

According to the present example embodiment, by lessening the switching voltage variation by expanding the perimeter of the copper wiring edge, it is possible to lessen the power consumption and element characteristic variation in the switching element constituting a large-scale crossbar switch array in programmable logic. By lessening the switching voltage, a cell transistor having a smaller driving force becomes available, and the driving force lowered due to scaling can be allowed. Therefore, according to the present example embodiment, a reduction in the area can be achieved in accordance with the scaling of the large-scale programmable logic using the switching element. By lessening the variation in element characteristics, it is possible to lessen the redundancy of the circuit and the margin of the transistor performance, which relieve the variation, and consequently programmable logic having higher performance and lower power consumption can be provided. According to the present example embodiment, since it is not necessary to use a latest exposure apparatus, the prototype mask and the process cost can be suppressed.

### Third Example Embodiment

Next, a semiconductor device according to a third example embodiment of the present invention will be described with reference to the drawings. The semiconductor device of the present example embodiment includes a two-terminal type switching element (also called a two-terminal switch).

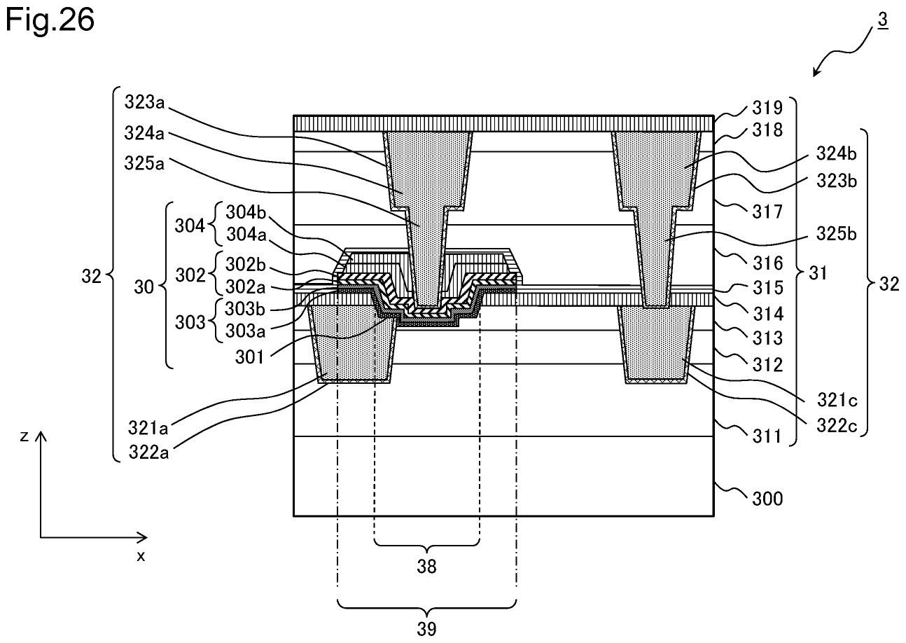

FIG. 26 is a schematic cross-sectional view illustrating an example of the configuration of a semiconductor device 3 according to the present example embodiment. As illustrated in FIG. 26, the semiconductor device 3 includes a substrate 300, a switching element 30, an insulating laminate 31, and a multilayer wiring layer 32. In the following description, in order to distinguish between multiple individual components, an alphabet character will be sometimes given at the end of the reference sign indicating the component. In a case where multiple individual components are not distinguished, the alphabet character for distinguishing between multiple components will be sometimes omitted.

The substrate 300 is a substrate on which a semiconductor element is formed. For the substrate 300, for example, a substrate such as a silicon substrate, a single crystal substrate, a silicon-on-insulator (SOI) substrate, a thin film transistor (TFT) substrate, or a substrate for liquid crystal manufacturing can be used. The switching element 30, the insulating laminate 31, and the multilayer wiring layer 32 are formed above the substrate 300.

The switching element 30 is a two-terminal type switching element (hereinafter referred to as two-terminal switch) formed inside the insulating laminate 31. The switching element 30 shares some components with the multilayer wiring layer 32. The switching element 30 includes a first electrode 301, a second electrode 302, a variable-resistance layer 303, and a hard mask layer 304. The second electrode 302 includes a lower second electrode 302a and an upper second electrode 302b. The variable-resistance layer 303 includes a first variable-resistance layer 303a and a second variable-resistance layer 303b. The hard mask layer 304 includes a first hard mask layer 304a and a second hard mask layer 304b.

The insulating laminate 31 is an insulation layer in which the switching element 30 and the multilayer wiring layer 32 are formed. The insulating laminate 31 includes an interlayer insulation layer 311, a Low-k layer 312, an interlayer insulation layer 313, a barrier insulation layer 314, a protective insulation layer 315, an interlayer insulation layer 316, a Low-k layer 317, an interlayer insulation layer 318, and a barrier insulation layer 319.

An opening 38 is formed in the barrier insulation layer 314 as in the second example embodiment. The opening 38 is made in such a way as to taper toward a depth direction (−Z direction). The opening 38 also spreads to parts of the interlayer insulation layer 313 and the first electrode 301. The circumferential edge of the opening 38 made in the barrier insulation layer 314, the interlayer insulation layer 313, and the first electrode 301 forms a tapered surface that tapers toward the depth direction. When the semiconductor device 2 is viewed from the viewpoint on an upper surface side, a region where the second electrode 302 is formed is called a second electrode region 39.

The multilayer wiring layer 32 is a wiring layer formed inside the insulating laminate 31. The multilayer wiring layer 32 includes a first wiring 321, a first barrier metal 322, a second barrier metal 323, a second wiring 324, and a via 325. A portion of the first wiring 321 in contact with the variable-resistance layer 303 denotes the first electrode 301. The first wiring 321 includes a first wiring 321a and a first wiring 321c. The first barrier metal 322 includes a first barrier metal 322a and a first barrier metal 322c. The second barrier metal 323 includes a second barrier metal 323a and a second barrier metal 323b. The second wiring 324 includes a second wiring 324a and a second wiring 324b. The via 325 includes a via 325a and a via 325b.

The semiconductor device 3 of the present example embodiment has a configuration in which the first wiring 221b, the first barrier metal 222b, and the first electrode 201b are omitted from the semiconductor device 2 of the second example embodiment. Since the other constituent members of the semiconductor device 3 are similar to the relevant constituent members of the semiconductor device 2 of the second example embodiment, a detailed description of the semiconductor device 3 will be omitted.

As described above, according to the present example embodiment, as in the first example embodiment, it is possible to provide a switching element that has been miniaturized without an increase in manufacturing cost and for which a switching voltage variation increase accompanied by miniaturization has been suppressed.

While the present invention has been particularly shown and described with reference to example embodiments thereof, the present invention is not limited to these example embodiments. It will be understood by those of ordinary skill in the art that various changes in form and details may be made therein without departing from the spirit and scope of the present invention as defined by the claims.

This application is based upon and claims the benefit of priority from Japanese patent application No. 2018-079029, filed on Apr. 17, 2018, the disclosure of which is incorporated herein in its entirety by reference.

### REFERENCE SIGNS LIST

1, 2, 3 semiconductor device
10 switching element
11 first electrode
12 second electrode
13 variable-resistance layer
14 first insulation layer
15 second insulation layer
20 switching element
21 insulating laminate
22 multilayer wiring layer
200, 300 substrate
201, 301 first electrode
202, 302 second electrode
203, 303 variable-resistance layer
204, 304 hard mask layer
211, 311 interlayer insulation layer
212, 312 Low-k layer
213, 313 interlayer insulation layer
214, 314 barrier insulation layer
215, 315 protective insulation layer
216, 316 interlayer insulation layer
217, 317 Low-k layer
218, 318 interlayer insulation layer
219, 319 barrier insulation layer
221 first wiring
222 first barrier metal
223 second barrier metal
224 second wiring
225 via

What is claimed is:

1. A semiconductor device comprising:
a first insulation layer;
a second insulation layer disposed on the first insulation layer and having an opening on an upper surface of the second insulation layer;
a first electrode embedded in the second insulation layer and having an end that is exposed at the opening;
a variable-resistance layer disposed on the first electrode and the second insulation layer in at least one region inside and around the opening; and
a second electrode that is disposed on the variable-resistance layer, wherein
the opening and the second electrode are formed in a shape stretched in at least one axial direction.

2. The semiconductor device according to claim 1, wherein
the variable-resistance layer is an ion conductive layer capable of conducting ions of a metal constituting the first electrode.

3. The semiconductor device according to claim 1, wherein at least one of a formation region of the opening and an opening region of the second electrode is elliptical.

4. The semiconductor device according to claim 1, wherein at least one of a formation region of the opening and an opening region of the second electrode is rectangular.

5. The semiconductor device according to claim 1, comprising the first electrode at two locations, wherein
the first electrodes at the two locations are disposed to face each other with an interval.

6. The semiconductor device according to claim 1, wherein the opening and the second electrode are formed in a shape stretched in a same direction, and
a formation region of the second electrode includes an opening region of the opening.

7. The semiconductor device according to claim 6, wherein the first electrode is formed in a shape stretched in one axial direction, and
a major axis direction of the first electrode coincides with major axis directions of the opening and the second electrode.

8. The semiconductor device according to claim 6, wherein the first electrode is formed in a shape stretched in one axial direction, and
a major axis direction of the first electrode coincides with minor axis directions of the opening and the second electrode.

9. A semiconductor device comprising:
a first insulation layer;
a second insulation layer disposed on the first insulation layer and has an opening on an upper surface of the second insulation layer;
at least one first wiring embedded in the second insulation layer and extended in a first direction, and at least one end of the at least one first wiring constitutes a first electrode exposed at the opening;
a variable-resistance layer disposed on the first wiring and the second insulation layer in at least one region inside and around the opening;
a second electrode disposed on the variable-resistance layer;
a third insulation layer disposed above the first electrode, the variable-resistance layer, and the second electrode;
at least one second wiring embedded in the third insulation layer via a barrier metal and extended in a second direction intersecting the first direction; and
a via embedded in the third insulation layer integrally with the second wiring via the barrier metal and electrically connected to the second electrode via the barrier metal, wherein
the opening and the second electrode are formed in a shape stretched in at least one axial direction.

10. The semiconductor device according to claim 9, wherein at least one switching cell constituted by the first electrode, the variable-resistance layer, and the second electrode is disposed at a position where the first wiring and the second wiring intersect each other.
